(19) United States
(12) Patent Application Publication
(10) Pub. No.: US 2011/0089958 A1
(43) Pub. Date: Apr. 21, 2011

(54) DAMAGE-SENSING COMPOSITE STRUCTURES

(75) Inventors: Harry C. MALECKI, Abingdon, MD (US); John Anthony HUGHES, Aberdeen, MD (US); Tushar K. SHAH, Columbia, MD (US)

(73) Assignee: APPLIED NANOSTRUCTURED SOLUTIONS, LLC, Baltimore, MD (US)

(21) Appl. No.: 12/900,405

(22) Filed: Oct. 7, 2010

Related U.S. Application Data
(60) Provisional application No. 61/253,021, filed on Oct. 19, 2009.

(51) Int. Cl. G01R 27/08; B32B 3/00; B32B 17/12; B32B 27/04

(52) U.S. Cl. 324/693; 428/292.1; 428/293.4; 428/297.4

(57) ABSTRACT

A composite includes a matrix material and a unidirectional array of carbon nanotube-infused fibers disposed in a portion of the matrix material. An article includes this composite and a network of electrodes disposed about the periphery of the composite. The electrodes send and receive an electrical charge. Such an article is included in a system, along with sensing circuitry and a source for supplying current to the network of electrodes. Such a system is used in a method that includes subjecting the article to a load that causes a condition in the composite including strain, fatigue, damage, or cracks, and monitoring the location of the condition.

### CROSS-REFERENCE TO RELATED APPLICATIONS

This application claims the benefit of priority to U.S. Provisional Application Ser. No. 61/253,021, filed Oct. 19, 2009, the entire contents of which are incorporated herein by this reference.

### STATEMENT REGARDING FEDERALLY SPONSORED RESEARCH OR DEVELOPMENT

Not applicable.

### FIELD OF THE INVENTION

The present invention relates to fiber materials, more specifically to fiber materials in composites.

### BACKGROUND OF THE INVENTION

Composites used in structural applications are susceptible to internal damage which can lead to catastrophic failure. Crack initiation and propagation (as a result of high stress, impact, or fatigue) in composite structures is difficult to identify without the use of specialized equipment. It would be beneficial to develop methods to monitor in situ damage of composite structures in various applications where identification of composite integrity is important to the system operation. The present invention satisfies this need and provides related advantages as well.

### SUMMARY OF THE INVENTION

In some aspects, embodiments disclosed herein relate to a composite that include a) a matrix material; and b) a first unidirectional array of carbon nanotube (CNT)-infused fibers disposed in at least a portion of the matrix material.

In some aspects, embodiments disclosed herein relate to an article that includes a) a composite that includes i) a matrix material; and ii) a first unidirectional array of carbon nanotube (CNT)-infused fibers disposed in at least a portion of the matrix material; and b) a network of electrodes disposed about the periphery of the composite for sending and receiving an electrical charge.

In some aspects, embodiments disclosed herein relate to a system that includes A) an article that includes i) a composite having a) a matrix material; and b) a first unidirectional array of carbon nanotube (CNT)-infused fibers disposed in at least a portion of the matrix material; and ii) a network of electrodes disposed about the periphery of the composite for sending and receiving an electrical charge; B) sensing circuitry connected to the network of electrodes for detecting a change in resistance across the composite; and C) a source for supplying current to said network of electrodes.

In some aspects, embodiments disclosed herein relate to a method includes 1) providing a system that includes A) an article which includes i) a composite including a matrix material a first unidirectional array of carbon nanotube (CNT)-infused fibers disposed in at least a portion of the matrix material; and ii) a network of electrodes disposed about the periphery of the composite for sending and receiving an electrical charge; B) sensing circuitry connected to the network of electrodes for detecting a change in resistance across the composite; and C) a source for supplying current to the a network of electrodes; 2) subjecting the article to a load that causes a condition in the composite selected from strain, fatigue, damage, and cracks; and 3) monitoring the location of the condition.

### BRIEF DESCRIPTION OF THE DRAWINGS

FIG. 1A shows a plurality of signal percolation pathways in an unstressed composite material having CNT-infused fibers.

FIG. 1B shows the reduction of percolation pathways in the composite material of FIG. 1A due to the strain of mechanical deformation.

FIG. 2A shows an exemplary structure for a composite “skin” having 4 stacked composite layers of unidirectional CNT-infused fibers. The middle two layers have the direction of the CNT infused fiber disposed 90 degrees relative to the outer two layers.

FIG. 2B shows a manufactured prototype “skin” having the layered structure shown in FIG. 2A. The CNT-infused fiber is a glass fiber. The “skin” is equipped with a plurality of electrodes that allow measurement of resistance changes across the composite structure.

FIG. 3A shows a side view of the prototype of FIG. 2B.

FIG. 3B shows a scanning electron micrograph of a cross section of one layer of unidirectionally aligned CNT-infused fibers from the prototype of FIG. 2B/3A. The void space between the CNT-infused fibers of the composite is filled an epoxy matrix material. The CNT-infused fiber is a glass fiber.

FIG. 3C shows a scanning electron micrograph of an intersection near two individual CNT-infused glass fibers.

FIG. 4 shows a unidirectional CNT-infused fiber panel with fibers aligned in the direction of the arrows. The panel is equipped with a plurality of transmitting electrodes 1A through 6A and a plurality of receiving electrodes 1B through 6B. Damage simulated as a ⅛ inch hole in the panel is shown as a circle in the vicinity of electrode pair 5A/5B. Mapped on the panel are the observed increases in resistance as measured along the fiber length. Damage near electrode pair 5A/5B is indicated by the large increase in resistance across this electrode pair.

FIG. 5A shows two individual unidirectional panels (plies) bonded together, oriented perpendicular to each other, with an insulating layer between the panels. Arrows indication direction of the fiber axis.

FIG. 5B shows a network of transmitting electrodes 1A through 12A and receiving electrodes 1B through 12B disposed on the bonded panels of FIG. 5A.

FIG. 6 shows the measured percent increase in resistance when a 9/64 inch hole was drilled in the center of a fabricated 3 inch×3 inch panel having the structure indicated in FIGS. 5A/B.

FIG. 7 shows the measured percent increase in resistance when a ¼ inch hole was drilled in the center of a fabricated 3 inch×3 inch panel having the structure indicated in FIGS. 5A/B.

FIG. 8 shows the measured percent increase in resistance when a 21/64 inch hole was drilled in the center of a fabricated 3 inch×3 inch panel having the structure indicated in FIGS. 5A/B.

FIG. 9 shows the measured percent increase in resistance when a 21/64 inch hole was drilled in the center and a second hole was drilled 0.75 inches×0.75 inches from the top left corner of a fabricated 3 inch×3 inch panel having the structure indicated in FIGS. 5A/B.

FIG. 10A shows a 7.5 inch×1 inch test strip panel having the 0/90 orientation of with no insulating layer. Electrodes were formed about a 0.20 inch diameter hole. Silver paint thickness of the electrode ring is 1/16 inch.

FIG. 10B shows a 7.5 inch×1 inch test strip panel having the 0/90 orientation of FIG. 5A/5B. Electrodes were formed about a 0.20 inch diameter hole. Silver paint thickness of the electrode ring is ⅛ inch.

FIG. 10C shows a 7.5 inch×1 inch test strip panel having the 0/90 orientation of FIG. 5A/5B. Electrodes were formed about a 0.20 inch diameter hole. Silver paint thickness of the electrode ring is ¼ inch.

FIG. 10D shows a depiction of the electrode configuration in the test panels of FIGS. 10A-10C.

FIG. 11 shows a graph of resistance versus electrode surface area for the test panels of FIGS. 10A-10C.

FIG. 12A shows a perpendicular pin electrode configuration for a 3-layered panel such as that shown in FIG. 5A.

FIG. 12B shows parallel pin electrode configuration for a 3-layered panel such as that shown in FIG. 5A.

FIG. 13 show a block diagram of a system for damage detection in accordance with embodiments of the invention.

FIG. 14 shows an input/output flow with a computer graphical user interface for a damage detection system and method.

FIG. 15 shows how a glass fiber material can be infused with CNTs in a continuous process for ballistic damage detection applications.

### DETAILED DESCRIPTION

The present disclosure is directed, in part, to tailored self-sensing composites that include CNT-infused fibers in at least a portion of a matrix material for damage detection applications. The composites can be utilized in any platform for monitoring the integrity of composite materials in structural components. Methods of the invention that utilize these self-sensing composites can utilize a variable source signal, while taking advantage of a scalable manufacturing process, to create a damage detection system having a high degree of control and sensitivity. Composites can be tailored to a specific applications and can be used to 1) detect types of damage to the composite through in situ monitoring, including monitoring of stresses on the materials prior, during, and/or after use; and 2) reduce the likelihood of catastrophic failure by providing structural enhancement and real time assessment of structural integrity.

One component of the composite materials of the invention is the CNT-infused fiber. Having CNTs infused on a fiber carrier facilitates manufacturing of large composite structures using conventional fiber-reinforced composite manufacture techniques to incorporate the CNT element throughout the composite or in strategic portions of a composite article. Because CNT density and distribution is tightly controlled with CNT-infused fibers compared to loose CNTs, the amount of CNTs can be substantially reduced. Moreover, having the CNTs on fibers allows for synergistic mechanical strength enhancement due to the CNT-fiber organizational hierarchy, allowing the CNTs to perform a dual role in both sensing damage as well as contributing to structural integrity by assisting in redistribution of load bearing stresses. The fiber carrier also facilitates strategic placement of CNTs throughout an entire 3-dimensional article or in a 2-dimensional “skin.” This strategic placement allows control of conductivity along the fiber axis and the transverse direction.

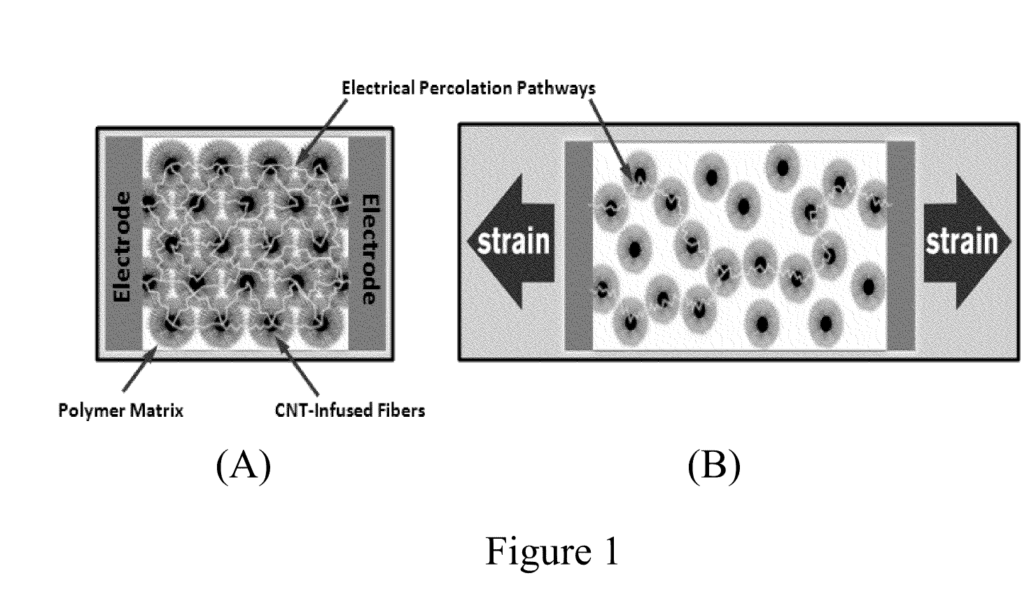

The properties of the composite can be modulated by control of CNT density, length, placement, and alignment, for example. Thus, composites can be tailored to a specific application and/or to detect any type of damage, as well as reduce the likelihood of damage. As shown in FIGS. 1A and 1B, the infused CNTs can affect the electrical properties of the composite and can serve to create percolation pathways that allow continuous, non-continuous, or intermittent monitoring of the stress on the composite material. As shown in FIG. 1A, the resting state of an exemplary composite of the invention has associated percolation pathways with measurable electrical properties such as resistance, for example, that can be monitored by an appropriately positioned pair of sensors, such as an electrode pair. As the material experiences strain, some of the CNT to CNT contacts are broken resulting in fewer operable percolation pathways, as shown in FIG. 1B. As a consequence, the resistance increases across the composite while it is experiencing this strain load, which can be reversible or not. Such reversibility can be assessed using methods of the inventions.

Composites made using the CNT-infused fibers bearing CNTs tailored for improved electrical properties can be used in damage sensing applications, as described above. Composites of the invention can also be used to improve composite strength. In a particular application, a CNT-infused fiber can be used in specific locations to improve composite strength as well as provide a means for damage detection at important structural components. One such application is in composite lap joints where one composite structure is bound to another composite structure (one structure can be perpendicular or parallel to the other). The bounded interface between the structures is of particular interest because it is considered the weak part of the structure. Utilizing the CNT-infused structure at this location allows for improved Interlaminar Shear Strength (ILSS) as well as the ability to provide damage detection.

Composites of the invention can be used in a method of detecting stresses within the composite material that includes monitoring modulated electrical signals (waveform along with amplitude and frequency) and assessing structural integrity with improved detection resolution and sensitivity. In some embodiments, amplitude measurements are used to measure strain. In some embodiments, phase is used to monitor crack propagation. In some embodiments, frequency is used to identify crack size. Composites, systems, and methods of the invention can be used in a variety of industries, for example, from the commercial airplane industry to ballistic armor damage detection on tanks and other military armored vehicles.

As used herein, the term “matrix material” refers to a bulk material than can serve to organize sized CNT-infused fiber material in particular orientations, including random orientation. The matrix material can benefit from the presence of the CNT-infused fiber material by imparting some aspects of the physical and/or chemical properties of the CNT-infused fiber material to the matrix material. Matrix materials can include, for example, an epoxy, a polyester, a vinylester, a polyetherimide, a polyetherketoneketone, a polyphthalamide, a polyetherketone, a polytheretherketone, a polyimide, a phenol-formaldehyde, and a bismaleimide. Matrix materials useful in the present invention can include any of the known matrix materials (see Mel M. Schwartz, Composite Materials Handbook (2d ed. 1992)). Matrix materials more generally can include resins (polymers), both thermosetting and thermoplastic, metals, ceramics, and cements.

As used herein, the term “carbon nanotube” (CNT, plural CNTs) refers to any of a number of cylindrically-shaped allotropes of carbon of the fullerene family including single-walled carbon nanotubes (SWNTs), double-walled carbon nanotubes (DWNTs), multi-walled carbon nanotubes (MWNTs). CNTs can be capped by a fullerene-like structure or open-ended. CNTs include those that encapsulate other materials.

As used herein, the term “infused” means bonded and “infusion” means the process of bonding. Such bonding can involve direct covalent bonding, ionic bonding, pi-pi, and/or van der Waals force-mediated physisorption. For example, the CNTs can be directly bonded to the fiber carrier covalently. Bonding can be indirect, such as CNT infusion to a fiber via a passivating barrier coating and/or an intervening transition metal nanoparticle disposed between the CNT and the fiber. In the CNT-infused fibers disclosed herein, the carbon nanotubes can be “infused” to the fiber directly or indirectly as described above. The particular manner in which a CNT is “infused” to a carbon fiber materials is referred to as a “bonding motif.” Regardless of the actual bonding motif of the CNT-infused fiber, the infusion process described herein provides a more robust bonding than simply applying loose, pre-fabricated CNTs to a fiber. In this respect, the synthesis of CNTs on catalyst-laden fiber substrates provides “infusion” that is stronger than van der Waals adhesion alone. CNT-infused fibers made by the processes described herein further below can provide a network of highly entangled branched carbon nanotubes which can exhibit a shared-wall motif between neighboring CNTs, especially at higher densities. In some embodiments, growth can be influenced, for example, in the presence of an electric field to provide alternative growth morphologies. The growth morphology at lower densities can also deviate from a branched shared-wall motif, while still providing strong infusion to the fiber.

In some embodiments, the present invention provides a composite that includes a matrix material and a first unidirectional array of carbon nanotube (CNT)-infused fibers disposed in at least a portion of the matrix material. Composite structures can include laminate “skin”-like structures, multi-laminate or layered structures, solid non-layered 3-dimensional articles and combinations of these composite structures. The term composite has the art recognized meaning in that the material is created by mechanically bringing two or more different materials together. The resulting material has characteristics that are different from the individual components (matrix and CNT-infused fiber) in isolation, or are enhanced by bringing the two materials together. Advanced composites utilize a combination of resins and fibers, often carbon/graphite, kevlar, or fiberglass with a matrix material, such as an epoxy resin. The fibers provide high stiffness, while the surrounding resin matrix holds the structure together. Without being bound by theory, the bulk phase or matrix material accepts the load over a large surface area, and transfers the load to the reinforcement fiber, which typically can carry a greater load. The present invention provides advanced composites utilizing a matrix material with a fiber that has CNTs infused on its surface. The presence of the CNTs infused to the fiber increases the mechanical strength characteristics conferred to the composite relative to the fiber alone. Moreover, the manner in which the fiber reinforcement phase is laid out throughout the matrix creates percolation pathways as illustrated in FIG. 1A. It is these pathways created by the CNT network that allow assessment of strain, fatigue, cracking, and other damage that the composite structure experiences.

Referring to FIG. 1A, there is shown a cross sectional view of an exemplary composite material of the present invention having CNT infused fibers in a matrix material, such as a polymer matrix. Application of a network of electrodes, such as transmitting and receiving electrodes, to opposing sides of the composite allows, for example, the measurement of resistance through the composite. In FIG. 1A the axis of the fiber is perpendicular to the plane of the drawing, i.e. coming out at the viewer. In the configuration shown, the electrodes are disposed perpendicular the fiber axis. In some embodiments, electrodes can be disposed along the fiber axis, while in still further embodiments, the electrodes can be disposed in a combination of along the fiber axis and perpendicular to the fiber axis. Regardless of the exact configuration, strain applied to the composite shown in FIG. 1B can result in loss of percolation pathways resulting in a measurable increase in resistance as the same current tries to traverse the composite with fewer viable percolation pathways. In a similar manner, it is possible, to create decreased resistance where a composite may experience a load, such as a compressive load, that increases CNT to CNT contacts resulting a greater number of viable percolation pathways.

While FIG. 1A shows a composite in which the CNT-infused fibers show a nominally radial display of CNTs about the fiber axis, in some embodiments, it is possible to redirect the general CNT orientation such that the CNTs lie along the fiber axis. In some such embodiments, the CNT-infused fiber can behave as a wire and the direction of the current can be favorably directed substantially along the fiber axis, with a lesser amount of current jumping from fiber to fiber in the transverse direction.

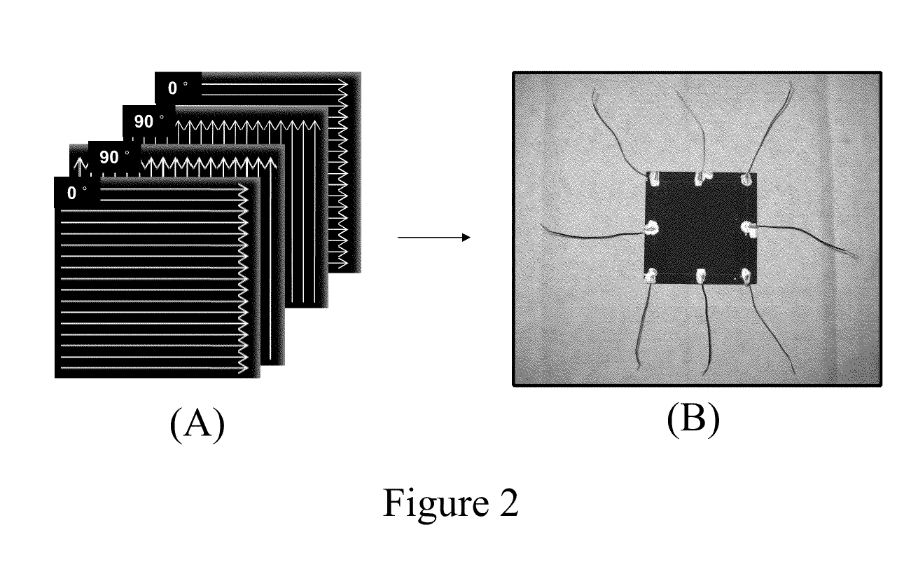

A unidirectional array of CNT-infused fibers can be achieved through conventional composite manufacturing techniques. For example, in some embodiments a spoolable quantity of CNT-infused fiber can be wound in one direction about a frame and the frame immersed in a curable matrix material to create a substantially two dimensional ply-like structure as exemplified in FIG. 2A (FIG. 2A shows 4 such ply like structures which were subsequently stacked). The individual ply unit has a unidirectional arrangement of the fiber material. One skilled in the art will appreciate that while FIG. 2A shows a square configuration, individual unidirectional arrays can take on other geometrical shapes including circular, rectangular, triangular, trapezoidal, and the like. A unidirectional array can be conformed to any geometry. An individual unidirectional array can be formed in large panels and unusual geometries cut from larger panels, for example. Because of the nature of the continuous CNT-infusion process, there are no particular limits on the dimensions of a composite having a unidirectional array of CNT-infused fibers. Wound panels can include sizes sufficient to accommodate dimensions that are useful in fabricating large structures such as airplane wings and/or a fuselage, boat hulls, and the like. Ply type configurations can be stacked into multilayered structures, as indicated in FIG. 2A. As shown in FIG. 2A pairs of plies can be offset with respect to the fiber direction (fiber direction shown by the arrows in FIG. 2A), or can be stacked in the same direction.

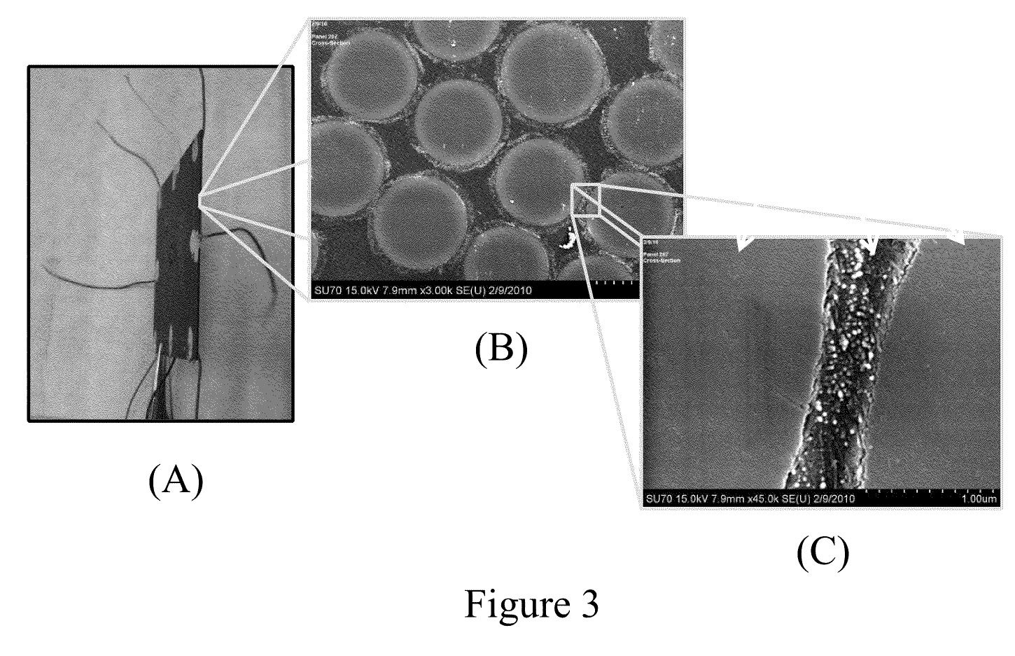

FIG. 2A shows a four-ply stack with a 0-90-90-0 orientation of the fibers. That is, the first pair of plies have the fibers disposed at a 90 degree angle to each other. The second pair of plies are oriented in the same direction, and the third and fourth ply again have fibers disposed at a 90 degree relative orientation. Thus, the first and fourth play are aligned in the same direction. FIG. 2B shows an actual composite that was manufactured in this manner that is equipped with transmitting and receiving electrodes. In the case of this stacked ply structure, electrode pairs will be oriented along the fiber axis for two plies and perpendicular to the fiber axis for the other two plies. A cross sectional end on view along the fiber axis of a CNT infused glass fiber composite is shown in FIGS. 3A-C. FIG. 3B shows a SEM image of individual glass fibers as gray circular structures with wisps of CNT which were grown on their surface. The void space in between is occupied by the composite matrix material. FIG. 3C is a close up view an interface between two adjacent glass fibers

In some embodiments, woven ply structures can be employed in composites of the invention. The fiber type employed in a woven structure can be uniform or two or more different fiber types can be woven. For example, a woven structure can include a mixture of glass fibers woven with ceramic fibers, either of which, or both of which can be infused with CNTs. In some embodiments a CNT-infused fiber can be woven together with a fiber lacking CNT infusion. In some such embodiments the fiber lacking CNT infusion can be an electrically insulating fiber. Exemplary combinations include, without limitation, CNT-infused glass fibers woven with ceramic fibers lacking CNT infusion, CNT-infused ceramic fibers woven with glass fibers lacking CNT infusion, CNT-infused carbon fibers woven with ceramic fibers lacking CNT infusion, and CNT-infused carbon fibers woven with glass fibers lacking CNT infusion. In some embodiments, woven structures can include one, two, three, four, or more fiber types woven in any conventional manner known in the art. In other embodiments, the woven structure can include a second CNT-infused fiber. In such embodiments the CNT density of the two fibers can be the same or different.

Composite materials of the present invention can utilize the plies and/or woven structures described herein above to create a three dimensional multi-laminate composite structure. Other methods can be applied to provide unidirectional arrays of fiber material such as injection molding, compression molding, vacuum infusion, pultrusion, extrusion, hand layup (open molding), resin transfer molding, vacuum assisted resin transfer molding, and the like. Depending on the method employed various configurations of composite structure are accessible.

In some embodiments, composites of the present invention include a matrix material and a CNT-infused fiber material. Composites of the present invention can have a matrix material selected from a thermoset, a thermoplastic, a ceramic, and a cement. Other matrix materials, such as metal matrix materials can also be employed, although the sensitivity in damage detection applications can be less than for other matrix materials.

Thermosetting resins useful as matrix materials include phthalic/maelic type polyesters, vinyl esters, epoxies, phenolics, cyanates, bismaleimides, and nadic end-capped polyimides (e.g., PMR-15). Thermoplastic resins include polysulfones, polyamides, polycarbonates, polyphenylene oxides, polysulfides, polyether ether ketones, polyether sulfones, polyamide-imides, polyetherimides, polyimides, polyarylates, and liquid crystalline polyester.

Ceramics useful as matrix materials include carbon ceramics, such as lithium aluminosilicate, oxides such as alumina and mullite, nitrides such as silicon nitride, and carbides such as silicon carbide. Cements useful as matrix materials include carbide-base cements (tungsten carbide, chromium carbide, and titanium carbide), refractory cements (tungsten-thoria and barium-carbonate-nickel), chromium-alumina, nickel-magnesia iron-zirconium carbide. Any of the above-described matrix materials can be used alone or in combination.

In some embodiments, composites of the present invention utilize infused CNTs selected from multi-walled CNTs, double-walled CNTs, single-walled CNTs; and mixtures thereof. In particular embodiments, composites of the invention use infused CNTs that are multi-walled CNTs. The electrical properties of the composites of the invention can be modified by applying various types, diameter, length, and density CNTs on the fiber. Electrical conductivity or specific conductance is a measure of a material's ability to conduct an electric current. CNTs with particular structural parameters such as the degree of twist, which relates to CNT chirality, can be highly conducting, thus exhibiting metallic properties. A recognized system of nomenclature (M. S. Dresselhaus, et al. Science of Fullerenes and Carbon Nanotubes, Academic Press, San Diego, Calif. pp. 756-760, (1996)) has been formalized and is recognized by those skilled in the art with respect to CNT chirality. Thus, for example, CNTs are distinguished from each other by a double index (n,m) where n and m are integers that describe the cut and wrapping of hexagonal graphite so that it makes a tube when it is wrapped onto the surface of a cylinder and the edges are sealed together. When the two indices are the same, m=n, the resultant tube is said to be of the “arm-chair” (or n,n) type, since when the tube is cut perpendicular to the CNT axis only the sides of the hexagons are exposed and their pattern around the periphery of the tube edge resembles the arm and seat of an arm chair repeated n times. Arm-chair CNTs, in particular SWNTs, are metallic, and have extremely high electrical and thermal conductivity. In addition, such SWNTs have-extremely high tensile strength. Multi-walled carbon nanotubes are conducting.

In some embodiments, the CNTs of the CNT infused fiber materials are grown directly on the fiber surface, creating “forests” of aligned CNTs extending radially off of the fiber surface. Thus, composites of the invention can have infused CNTs that are aligned substantially perpendicular to the fiber axis. Total circumferential coverage of CNTs can be achieved over the entire length of each fiber. In some embodiments, the CNT growth process can be utilized to create CNT density gradients across the length of the fiber. Such gradients can be used to create gradient electrical conductivity within the composite structure.

In some embodiments, composites of the invention can have infused CNTs that are aligned substantially along the fiber axis. Re-orienting the infused CNTs for alignment parallel to the fiber axis can be accomplished using mechanical techniques, such as an extruding/pultrusion process. Other methods can be used in conjunction with, or in lieu of mechanical CNT re-orienting. Exemplary processes include realignment in an electric field and chemical methods using particular solvents and/or surfactants. Thus, CNTs can be made to conform to the direction of the fiber axis along a continuous fiber surface. The CNT infusion process described herein further below lends more control over the orientation of CNTs within the composite via the organization of the CNTs on the fiber carrier. CNT-infused fibers also provide better control of CNT dispersion throughout the composite relative to methods employed in the art to make CNT-containing composite materials, especially those employing loose CNTs. They are also more cost effective than high CNT density fibers such as CNT-only fibers, yarns, and ropes.

In some embodiments, composites of the invention can have infused CNTs present in a range from between about 0.01 percent to about 30 percent by weight of the composite, including 0.01, 0.5, 1.0, 1.5, 2.0, 2.5, 3.0, 3.5, 4.0, 4.5, 5.0, 6.0, 7.0, 8.0, 9.0, 10.0, 11.0, 12.0, 13.0, 14.0, 15.0, 16.0, 17.0, 18.0, 19.0, 20.0, 25.0, and 30.0, including all values in between and fractions thereof. At the high end, CNT percolation pathways can become quite numerous and composite damage detection can be less sensitive because the percent change in viable pathways can be very small. At the lower end of CNT loading, sensitivity can be higher because with fewer initial viable percolation pathways, any pathway disconnect can have a substantially larger impact on observed changes in resistance, for example. Nonetheless, depending on the targeted sensitivity, damage sensing can be operable across the entire range from 0.01 percent to about 30 percent by weight of the composite. In particular embodiments, the range of CNT in the composite is in a range from between about 0.01 percent to about 1.0 percent by weight, including 0.01, 0.02, 0.03, 0.04, 0.05, 0.06, 0.07, 0.08, 0.09, 0.10, 0.15, 0.20, 0.25, 0.30, 0.35, 0.40, 0.45, 0.50, 0.55, 0.60, 0.65, 0.70, 0.75, 0.80, 0.85, 0.90, 0.95, 1.00 percent by weight, including any value in between. This range of CNT loading in the composite can be used where a high level of sensitivity is desired.

CNTs of a length which will provide effective CNT to CNT bridging is employed to create percolation pathways (see FIGS. 1A/B) which imparts composite conductivity. Because fiber spacing is typically equivalent to or greater than one fiber diameter (5-50 microns), CNTs shorter than this length can reduce effective electrical pathways. Longer CNTs can create entanglement which can improve conductive properties as well as damage sensing capabilities, sensitivity, and resolution. Infused CNTs can vary in length ranging from between about 1 micron to about 500 microns, including 1 micron, 2 microns, 3 microns, 4 micron, 5, microns, 6, microns, 7 microns, 8 microns, 9 microns, 10 microns, 15 microns, 20 microns, 25 microns, 30 microns, 35 microns, 40 microns, 45 microns, 50 microns, 60 microns, 70 microns, 80 microns, 90 microns, 100 microns, 150 microns, 200 microns, 250 microns, 300 microns, 350 microns, 400 microns, 450 microns, 500 microns, and all values in between. CNTs can also be less than about 1 micron in length, including about 0.5 microns, for example. CNTs can also be greater than 500 microns, including for example, 510 microns, 520 microns, 550 microns, 600 microns, 700 microns and all values in between. In some embodiments, composites of the invention have infused CNTs ranging in length from between about 100 nanometers to about 5 microns.

Composites of the invention can include CNT-infused fibers based on fibers selected from glass fibers, aramid fibers, other organic fiber, such as cotton fibers, ceramic fibers, and mixtures thereof. CNT-infused fiber materials can include filaments, a fiber yarn, a fiber tow, a tape, a fiber-braid, a woven fabric, a non-woven fiber mat, a fiber ply, and 3D woven structures. The CNT infusion process has been described in WO/2008/085634 and pending U.S. patent application Ser. No. 11/619,327 which are incorporated by reference herein in their entirety. Briefly, fibers to be used in generation of the composite are treated with a layer of CNT-initiating catalyst nanoparticles which are then exposed to a CVD-based process used to grow CNTs continuously, in line. The resulting CNT-infused fiber can be tailored with specific types of CNTs on the surface of fiber such that various properties can be achieved. The process is amenable to scale up of spoolable quantities of fiber material. For example, the continuous in line process can achieve CNT infused fibers on spoolable lengths ranging from about one pound spools to about 50 pound spools of fiber.

In some embodiments, composites of the invention include a first unidirectional array of CNT-infused fibers having a fiber structure that is a continuous fiber. Consistent with the ability to process large scale continuous lengths of CNT infused fibers, such continuous fibers are readily applied to the manufacture of a composite after any post CNT-infusion treatments. Such post CNT-infusion treatments can include, without limitation, reorientation of the CNTs, functionalization of the CNTs, and coating of the CNTs. Functionalization can include, for example, fluorination of the CNTs, acid etching, and acid etching combined with chemistry that utilizes any exposed functionality resulting from the etching process. Exemplary chemistry includes that of the exposed ketone, aldehyde, and carboxylic acid functional groups. Thus, post etching chemistry can include, for example, ester bond formation, amide bond formation, Schiff base formation, reductive amination, and the like. Such functionalization can be used to enhance, for example, the interface between the CNT-infused fiber and the matrix material. Coatings can also be used to enhance the CNT-infused fiber-matrix material interface. In some embodiments, such coatings can include, for example, the Kentera system (Zyvex Performance Materials, Columbus, Ohio).

In alternate embodiments, composites of the invention can utilize a first unidirectional array of CNT-infused fibers in which the fiber material includes a plurality of discontinuous fibers. In such embodiments, the continuous CNT infusion manufacturing procedure can be employed to generate CNT-infused continuous fibers. The CNT-infused continuous fibers can be subsequently passed through a chopper gun, for example, to create smaller fiber fragments. In some embodiments, the resultant CNT-infused discontinuous fibers can be aligned within the matrix material by techniques apparent to those skilled in the art, including orientation by pultrusion, for example.

In some embodiments, composites of the invention include a first unidirectional array of CNT-infused fibers disposed at the surface of the composite. In some such embodiments the composite can be incorporated in an article which includes a continuous matrix material with the first unidirectional array of CNT-infused fiber disposed only at or near the surface of the article. In other embodiments, the CNT-infused fiber can be pre-fabricated as a skin that can be overlaid and bonded on top of an article. In such embodiments, the matrix material of the composite can be the same or different composition from that of bulk article. In still further embodiments, a skin can be applied as above and subsequently bonded to the article in a laminate-type structure. In some embodiments, multiple skin-like structures can be stacked to form multi-laminate skins which are bonded together using conventional techniques known in the art.

For any of the above mentioned configurations, bonding can include melting the matrix of the composite of the invention onto the article to form a continuous matrix where, for example, the bulk article is fabricated from the same matrix material as the composite, or is of a different material that melts at a similar temperature. Bonding can also be achieved through the use of adhesives. In some embodiments, the adhesive employed is electrically insulating, although the adhesives can be any type including, for example, contact adhesives, hot melt adhesives, solvent-based adhesives, and multi-part reactive adhesives. Exemplary adhesives include, without limitation, cyanoacrylate, epoxy, nitrocellulose, rubber adhesives, such as polychloroprene, thermoplastics, and polyvinyl acetate.

In some embodiments, composites of the invention can further include a second unidirectional array of CNT-infused fibers. FIG. 2A is exemplary of a multi-laminate ply structure that includes 4 unidirectional arrays of CNT-infused fibers. One skilled in the art will appreciate that any number unidirectional arrays can be stacked in this manner with any relative orientation. The second unidirectional array of CNT-infused fibers can be disposed at an angle from between about 0 degrees to about 90 degrees, relative to the first unidirectional array of CNT-infused fibers. Thus, for example, the first and second unidirectional arrays can be disposed at angles that have a relative orientation of 1, 2, 3, 4, 5, 6, 7, 8, 9, 10, 11, 12, 13, 14, 15, 16, 17, 18, 19, 20, 25, 30, 35, 40, 45, 50, 55, 60, 65, 70, 75, 80, 85, and 90 degrees, including any value in between and fractions thereof.

In some embodiments a composite of the invention includes a first unidirectional array of CNT-infused fiber, a second unidirectional array, a third unidirectional array, a forth unidirectional array, a fifth unidirectional array, and so on, including 6, 7, 8, 9, 10, 11, 12, 13, 14, 15, 16, 17, 18, 19, 20, 25, 30, 40, 50, 60 unidirectional arrays of CNT-infused fibers, including any number in between. Any number of unidirectional arrays can be assembled into an article having any shape or dimensions. For example, stacked circular arrays can be used to assemble cylindrical objects, stacked rectangular arrays can be used to assemble 3-dimensional rectangular objects, and so on.

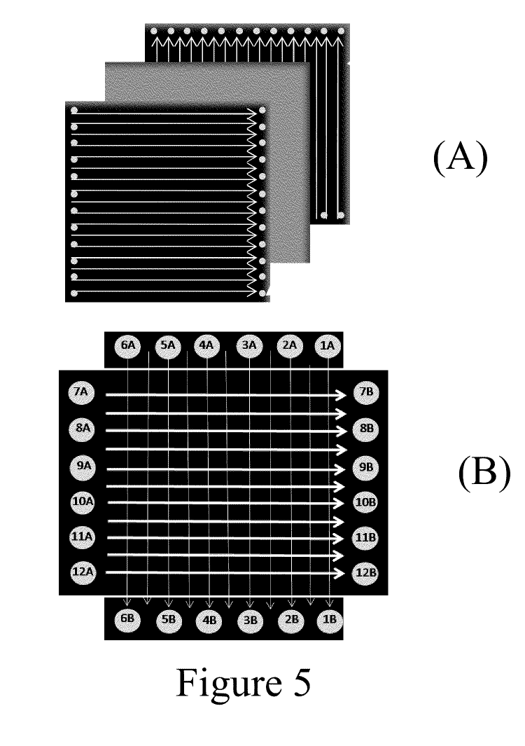

In some embodiments, composites of the invention having a first and second unidirectional array of CNT-infused fibers can further include an insulating layer disposed between the first unidirectional array of CNT-infused fibers and the second unidirectional array of CNT-infused fibers, as shown in FIG. 5A. Likewise, multiple insulating layers can be present between each unidirectional array of CNT-infused in a multi-laminate structure having more than one unidirectional array of CNT-infused fibers. Without being bound by theory, the insulating layer can be beneficial for enhancing detection of in-plane stresses in a composite structure by minimizing transverse current perpendicular to the fiber direction.

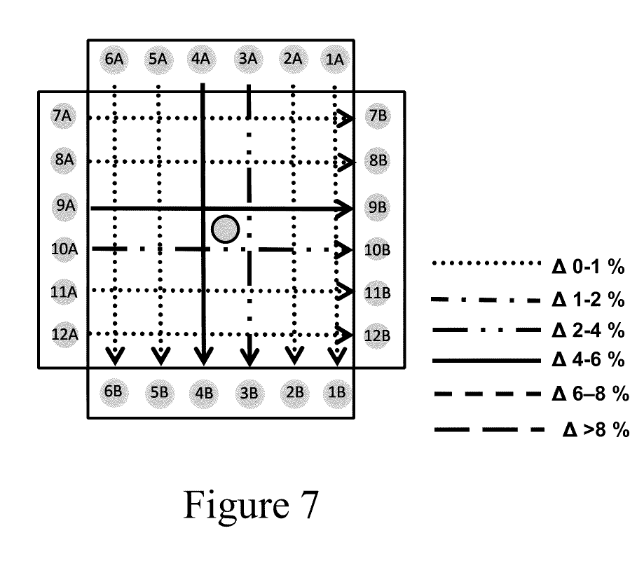

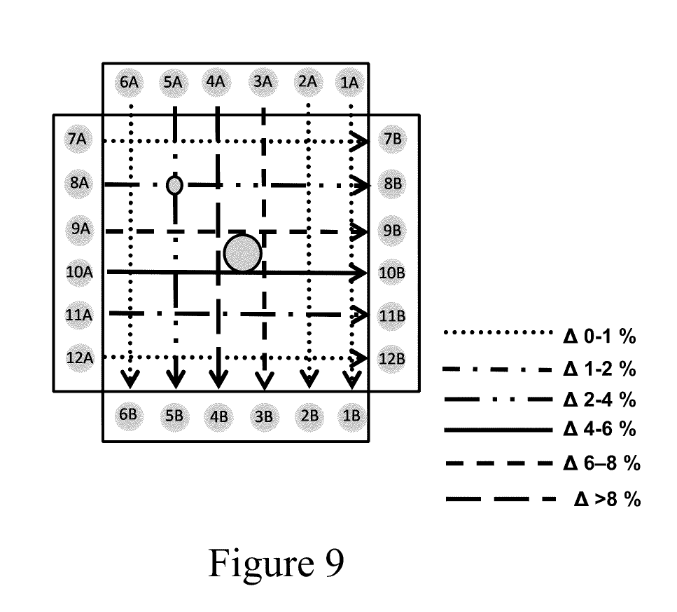

In some embodiments, the present invention provides an article that includes a 1) a composite structure of the invention having a matrix material and a first unidirectional array of carbon nanotube (CNT)-infused fibers disposed in at least a portion of the matrix material and 2) a network of electrodes disposed about the periphery of the composite for receiving information related to resistance changes across the composite The a network of electrodes allow mapping the location of strain, fatigue, damage, and cracks in the composite by measuring resistance changes across the composite. Exemplary articles that include the composites of the invention with networks of electrodes are shown in FIGS. 2B, 3A, 4, 5B, 6-9, 10A-C, and 12A and B. In particular embodiments, articles of the invention comprise a ply type structure with a unidirectional array of CNT-infused fibers in a cured matrix material to provide a panel. Such panels can serve as a skin structure to be applied to larger articles. Alternatively, multi-laminate articles are manufactured by stacking individual plies.

In some embodiments, articles of the invention employ a network of transmitting and receiving electrodes disposed about the periphery of the composite. In some embodiments, the a network of electrodes is engaged with sensing circuitry that can be used to measure and map location of strain, fatigue, damage, and cracks in the composite.

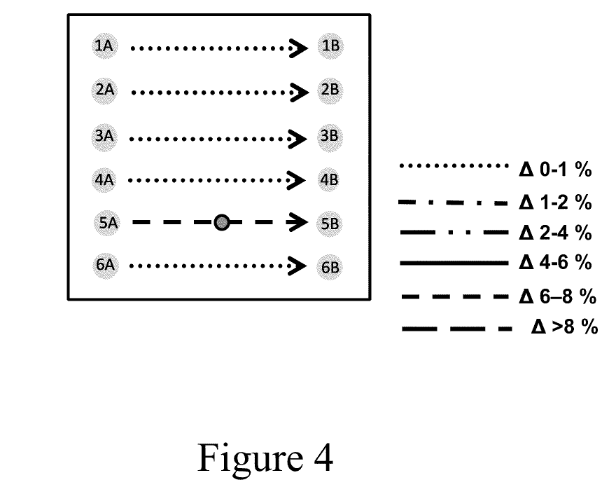

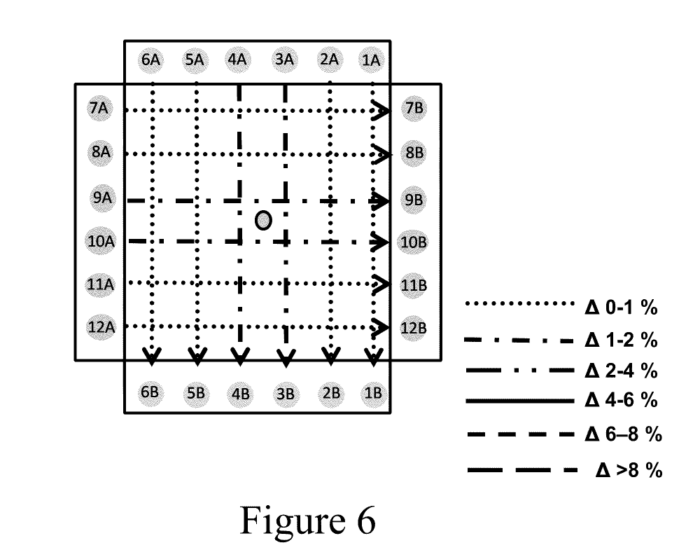

In some embodiments, an electrode network is oriented along the fiber axis as indicated in FIG. 4, for example. In some embodiments, an electrode network is present both along the fiber axis and perpendicular to the fiber axis, as exemplified in FIG. 2B. With respect to FIG. 2B, in particular, where multiple electrodes are disposed about the entire periphery of the article, and the multiple unidirectional arrays of CNT-infused fibers are employed at a 90 degree relative orientation, a single electrode pair will be disposed along the fiber axis relative to the first unidirectional array and perpendicular relative to the second unidirectional array. In some embodiments, electrodes along the periphery can be any size and in any number up to manufacturing tolerance limits. FIGS. 5B and 6-9 exemplify a 6×6 network of electrode pairs in an article of the invention having a layered structure shown in FIG. 5A with two unidirectional arrays of CNT-infused fibers disposed at a 90 degree relative orientation with an insulating layer disposed between the unidirectional arrays. Thus, in a multi-laminate article, these electrode pairs are spatially addressable. This allows articles of the invention to be used in a context that allows measurement of the location of stresses on the composite article. These stresses can be determined, for example, by changes in the electrical properties of the composite measured with the electrode network. FIGS. 6-9 show measured changes in resistance for each electrode pairing when damage simulated as a hole is drilled through the composite article.

In some embodiments, articles of the invention can use any of the matrix materials employed to generate a composite including, without limitation, a thermoset, a thermoplastic, a ceramic, and a cement. Other matrix materials can also be employed, with weakly conducting matrix materials providing for higher sensitivity in damage detection applications. Articles of the invention can employ CNTs in the CNT-infused fibers that are selected from multi-walled CNTs, double-walled CNTs, single-walled CNTs; and mixtures thereof. In particular embodiments, the article of the invention employs infused CNTs that are multi-walled CNTs. The multi-walled CNTs offer good electrical conductivity while also lending strength enhancing properties to the article. This is particularly useful in applications where the article is under continuous stress. Articles of the invention can have infused CNTs that are aligned substantially along the fiber axis or substantially perpendicular to the fiber axis. In complex articles, the composite structure can be designed to include a unidirectional array of CNT-infused fibers at strategic locations that are more likely to fail and can benefit from the strength enhancing characteristics imparted by the presence of the CNT-infused fiber.

Articles of the invention can have infused CNTs present in a range from between about 0.01 percent to about 1 percent by weight of the composite, for each individual unidirectional array employed as described above. It is understood that when factoring in other components of the article, such as insulating layers and electrode materials, the article itself can have an overall CNT loading that is correspondingly lower.

In some embodiments, articles of the invention can have infused CNTs that range in length from between about 100 nanometers to about 5 microns as employed in the individual composites having single unidirectional arrays. In some embodiments, where no insulating layers are used in the article, it can be advantageous to use shorter CNTs to reduce transverse electron transfer. Infused CNTs incorporated in articles of the invention can vary in length ranging from between about 1 micron to about 500 microns, including 1 micron, 2 microns, 3 microns, 4 micron, 5, microns, 6, microns, 7 microns, 8 microns, 9 microns, 10 microns, 15 microns, 20 microns, 25 microns, 30 microns, 35 microns, 40 microns, 45 microns, 50 microns, 60 microns, 70 microns, 80 microns, 90 microns, 100 microns, 150 microns, 200 microns, 250 microns, 300 microns, 350 microns, 400 microns, 450 microns, 500 microns, and all values in between. CNTs can also be less than about 1 micron in length, including about 0.5 microns, for example. CNTs can also be greater than 500 microns, including for example, 510 microns, 520 microns, 550 microns, 600 microns, 700 microns and all values in between. In some embodiments, articles of the invention include composites having infused CNTs ranging in length from between about 100 nanometers to about 5 microns.

Articles of the invention can incorporate CNT-infused fibers that are the same as the constituent composites having a single unidirectional array and include without limitation, glass fibers, aramid fibers, ceramic fibers, and mixtures thereof. Articles of the invention can include composites having any type of CNT-infused fiber, including those based on fibers selected from other organic fiber, such as cotton fibers. CNT-infused fiber materials can include filaments, a fiber yarn, a fiber tow, a tape, a fiber-braid, a woven fabric, a non-woven fiber mat, a fiber ply, and 3D woven structures.

As with composites of the invention, articles of the invention can have a first unidirectional array of CNT-infused fibers that includes a continuous fiber or a plurality of discontinuous fibers. In the latter case the discontinuous fibers can be oriented to control the relative CNT orientation.

Articles of the invention can have a first unidirectional array of CNT-infused fibers that is disposed at the surface of the article. Alternatively, articles of the invention can include one or more unidirectional arrays of CNT-infused fibers throughout the entire article, including a second unidirectional array of CNT-infused fibers, a third, fourth, fifth, and sixth array, and so on, up to a sufficient amount to include the entirety of an article.

As with composites described herein above, articles of the invention can have a second unidirectional array of CNT-infused fibers is disposed at an angle from between about 0 degrees to about 90 degrees, relative to a first unidirectional array of CNT-infused fibers, including any relative angle in between, and fractions thereof. Any number of unidirectional arrays may be incorporated into an article. Articles of the invention can further include an insulating layer disposed between any first unidirectional array of CNT-infused fibers and a second unidirectional array of CNT-infused fibers, as described herein above with respect to composites. The relative orientation of each unidirectional array of CNT-infused fibers incorporated in an article of the invention is controlled during composite manufacture and allows for precise electrode patterning about the article.

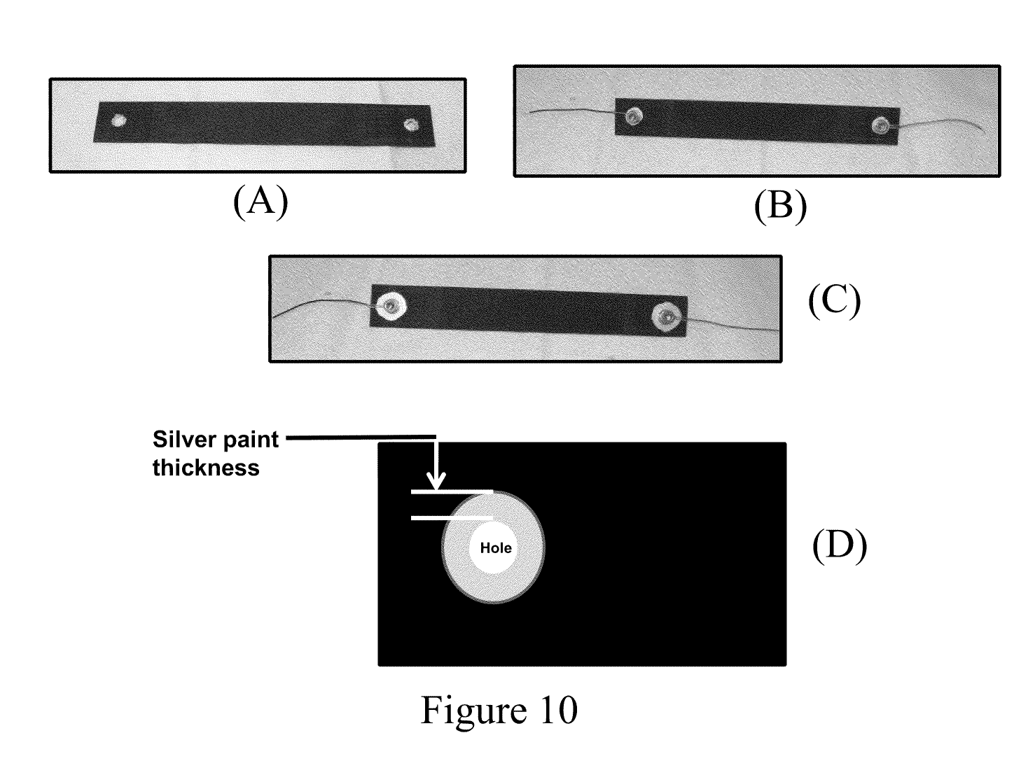

In some embodiments, articles of the invention include a network of electrodes include a network of transmitting and receiving electrodes in which the electrodes are fabricated with silver paint, as shown in FIGS. 10A-D. One skilled in the art will recognize that silver painted electrodes are merely exemplary and that the electrode material can include any metals known in the art used in the manufacture of electrodes, such as copper, lithium, iron, cobalt, molybdenum, nickel, silver, lanthanum, manganese, titanium, aluminum, platinum, zirconium, yttrium, scandium, strontium, and vanadium and salts thereof, and mixtures thereof, including alloys.

Electrodes can be of any size, although a greater number of smaller electrode pairs can be useful for increased sensitivity. FIGS. 10A-10C show test strip composite panels configured with a unidirectional array of CNT-infused glass fibers wound around the long direction of the panel. This exemplary panel was constructed with a curable epoxy resin. A uniform size hole was drilled into each end of the test panel and a thickness of paint around the hole was increased going from 10A to 10B to 10C. This thickness of the electrode is illustrated in FIG. 10D.

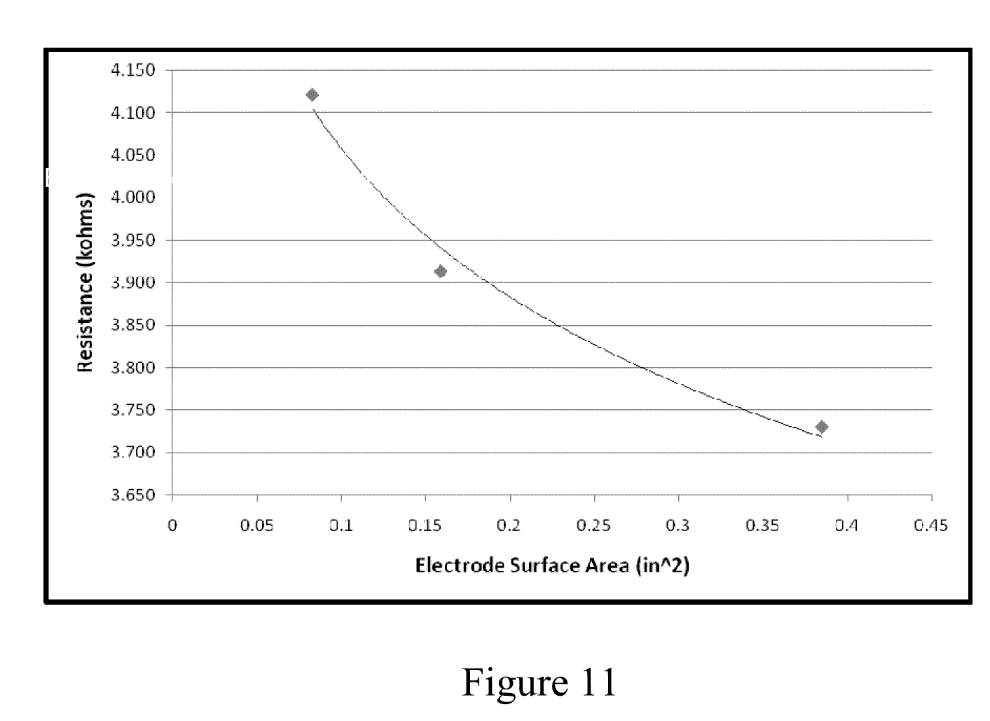

As indicated in FIG. 11, there is a relationship between the observed resistance between two electrodes and the size of the electrode. With fewer percolation pathways, the measured resistance across the panel increases for a given current as the size of the electrode decreases. Without being bound by theory, a smaller electrode provides electrical current to a fewer number of viable percolation pathways compared to a larger electrode. In the context of damage detection, when only a small number of percolation pathways are broken, the smaller electrode experiences a large change in resistance because the impact of any lost pathways is significant. By comparison, in the extreme of a continuous electrode across the entire panel, the initial number of percolation pathways can be quite large and the impact of the loss of only a small number of percolation pathways can result in a small observed change in resistance. Nonetheless, at either extreme of very small or very large electrode pairs, damage detection is readily measured and a balance between ease of manufacture and sensitivity can be achieved.

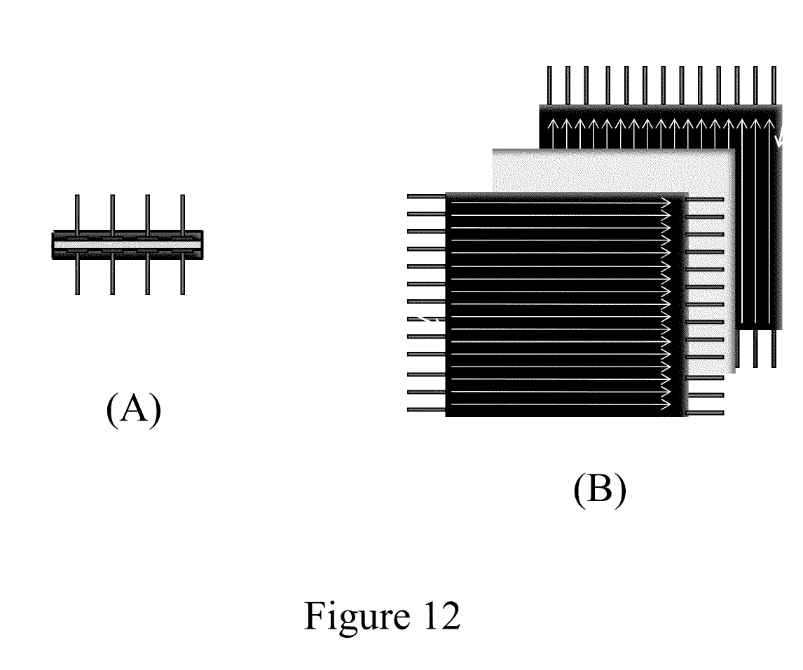

In other embodiments, a network of electrodes in the form of a network of transmitting and receiving electrodes include embedded copper pin electrodes, as shown in FIGS. 12A and 12B. As shown in FIG. 12A, electrode pins can be assembled in a trilayer structure (first unidirectional array-insulator-second unidirectional array) with the pins oriented perpendicular to the plane of the article. As shown in FIG. 12B, the electrode pins can also be oriented in the plane of the article and along the same direction as the fiber axis in a unidirectional array. FIG. 12B shows two unidirectional arrays each having electrode pins disposed parallel to their respective fiber direction. The two unidirectional arrays are disposed at a 90 degree relative orientation and an insulating materials is disposed between the two arrays. In some embodiments, electrodes can also be fabricated by any other technique known in the art, including without limitation, lithography, printing, and the like. Electrodes can consist of embedded metal electrodes, metal films applied to the surface of the composite via sputtering, evaporation, plasma, or any other gas phase particle deposition technique. Integrated electrodes can also be created by connecting loose ends of CNT-infused fibers themselves.

In some embodiments, the present invention provides a system that includes 1) an article as described herein above, 2) a source for supplying current to the one or more sensors; 3) a computer equipped to receive resistance data; the computer can be provided with software having a damage sensing algorithm; and 4) a graphical user interface displaying the location of strain, fatigue, damage, and cracks in article's composite structure.

In some embodiments, the present invention provides a system that includes an article that incorporates a composite having a matrix material and a first unidirectional array of carbon nanotube (CNT)-infused fibers disposed in at least a portion of the matrix material and sensing circuitry connected to the composite for detecting a change in resistance across the composite.

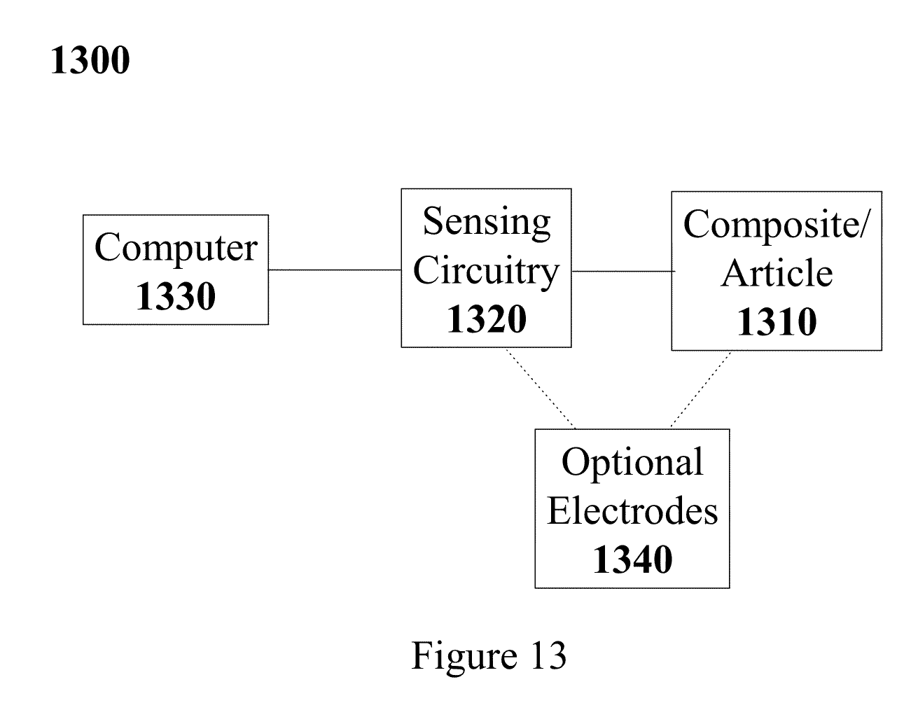

Referring now to FIG. 13, there is shown a system of the invention 1300 having a composite/article 1310 which can be operably-linked to sensing circuitry 1320. Sensing circuitry 1320 is then linked to a computer 1330, which may optionally include a graphical interface, such as a monitor, which can be used to display the location of damage or stresses within composite/article 1310. In some embodiments, sensing circuitry 1320 can have its own display obviating the need for computer 1330. System 1300 can further optionally include a network of electrodes 1340 acting as an intermediary between composite/article 1310 and sensing circuitry 1320. System 1300 can incorporate a source for supplying current to composite/article 1310 and, when in use, the network of electrodes 1340. In alternate embodiments, current can be provided passively to the system. Systems of the invention can employ the sensing circuitry to measure and map the location of strain, fatigue, damage, and/or cracks in the composite.

Systems of the invention can include a computer equipped to receive resistance data from the sensing circuitry, and the computer can be provided with software having a damage sensing algorithm. This algorithm can include code for display on a graphical user interface displaying the location of strain, fatigue, damage, and cracks in the composite.

Systems of the invention can be incorporated into any setting where damage detection may be useful. For example, a system may be installed as part of an aircraft to monitor stresses/damage to the wings or fuselage, or as part of a boat or tank hull, and the like. The systems of the invention can use a source for supplying current that can be an AC or DC source. Measurements of electrical properties, such as resistance, can be monitored and with the aid of a computer equipped with damage sensing algorithm software, provide output to a user with a graphical interface. This allows for continuous or intermittent monitoring of damage.

As shown in FIG. 13, a system generally includes a monitoring station which collects sensed data. The sense data is transmitted to computer having a damage sensing algorithm. This algorithm can collect and process of multiple measurements simultaneously. In some embodiments, the algorithm can be trained to recognize the resting state of an article and use this resting state as a zero point measure of stresses. In some embodiments, the algorithm can be trained to adapt to permanent changes in the article due to stresses and recalibrate a zero point to measure further forces applied to the article. The algorithm employed can utilize modeling data to optimize detection functions. Ultimately any damage detected by application of the algorithm can be communicated to an end user through a graphical interface. The graphical interface can provide information related to the structural integrity of the article, locations of current stresses on the article, and the like.

In some embodiments, the present invention provides a method that includes providing the aforementioned systems of the invention and subjecting the article to a load that causes a condition in the article/composite selected from strain, fatigue, damage, and cracks, and monitoring the location of the condition via a graphical interface.

In some embodiments, a method includes monitoring a modulated electrical signal (waveform along with amplitude and frequency) to provide improved detection resolution and sensitivity to damage a composite material have CNT-infused fiber materials. Amplitude can be used to measure strain, phase can be used to monitor crack propagation, and frequency used to identify crack size.

Thus, in some embodiments, bandstop frequency of parallel RLC-circuit sweeping frequency is used to determine a calculated bandstop capacitance which can be related to crack size:

$${ω}_{0} = \frac{1}{\sqrt{L C}}$$

Damage detection in composites can be achieved by measuring an initial resistance value through at least a set, series, or array of electrodes placed along the periphery of the area of interest, in operable contact with the CNT-infused fiber materials in the composite. Regardless of the means used to obtain the electrical resistivity, the resistivity can be continuously measured and compared to the original value. Variations in resistivity can be related to the presence of increased strain, crack initiation, crack propagation, or more severe forms of damage, which would be a result of broken percolation pathways in the CNT network. In some embodiments, monitoring is achieved by use of an electrical signal sent through the structure to detect damage.

The resistivity can be continuously measured and compared to the original value, in accordance with embodiments of the invention. Variations in resistivity can be related to the presence of increased strain, crack initiation, crack propagation, or more severe forms of damage, which would be a result of broken percolation pathways in the CNT network. While this technique, can identify composite integrity, resistivity measurements alone can provide too little data, sensitivity, or resolution to completely or even sufficiently characterize damage. As a result, in some embodiments, the use of an attenuated electrical signal through the structure can be used as a means for detecting damage as well. Much like vibrations or ultrasonic waves can be used in metal structures to detect imperfections or fatigue based inclusions in a structure, an electrical signal (a sine wave of a known amplitude and frequency) can be transmitted through electrodes in a CNT-infused composite structure to detect damage.

In some embodiments, a generated wave is compared to a received wave. One electrode along an array is used as a transmitter while all other electrodes are used as receivers. The transmitter electrode sends out a signal which is received and processed at each receiver location. The attenuated signal can be swept through a range of signal frequencies from Hz-GHz. Once a complete sweep is completed by one electrode, a subsequent electrode in the array takes on the role as the transmitter and all other electrodes are receivers. The process repeats itself, changing transmission points to improve overall detection accuracy, resolution, and sensitivity. Such signal scans can take place in less than a second using modern electronics control methods. Collected signals can be compared to the original transmitted signal using a similar circuit used in radar. Each electrode can be switched between transmission/reception modes via a local electrode specific duplexer. Received signals can be compared to the original signal (generated by a local oscillator) using a signal mixer. The changes observed in phase and amplitude at different frequencies are induced by mechanical strain, crack initiation and/or propagation, or other forms of damage which can be captured and processed by a monitoring system. This system can identify the type and degree of damage with high resolution and sensitivity. The amplitude of the wave provides similar information to that of resistivity—particularly how much the material is straining under stress. Phase changes can be directly related to the shape of any obstructions or cracks it encounters along its way through a structure (provide information on cracks—size and shape). Varying frequencies will provide the varying signal “magnifications”. Signals of varying frequency will more readily recognize features on length scales within their given wavelength. If micro-cracks are of interest, signals in the MHz range can be targeted to provide the greatest resolution in the micron length scale. Combining the information from the signal can provide a high resolution, sensitive, and accurate image or mapping (in 2D or 3D depending on electrode arrangement) of a composite structural integrity.

Advantageously the methods of the present invention assess damage detection using a source with three distinct characteristics: wave amplitude, phase, and frequency. Any variation in wave amplitude or phase of the source signal as it is passed through the composite can be directly related to size, shape, and location of damage within the structure. Sensitivity of the source signal can also be varied by changing the frequency of the source signal.

Finally, although the present application focuses on applications related to damage sensing in composite materials, one skilled in the art will recognize that the CNT-infused fiber can impart any number of additional properties to the composite such as tensile strength, Young's Modulus, interlaminar shear strength (ILSS), shear modulus, toughness, compression strength, compression modulus, density, EM wave absorptivity/reflectivity, acoustic transmittance, electrical conductivity, and thermal conductivity.

Tensile strength can include three different measurements: 1) Yield strength which evaluates the stress at which material strain changes from elastic deformation to plastic deformation, causing the material to deform permanently; 2) Ultimate strength which evaluates the maximum stress a material can withstand when subjected to tension, compression or shearing; and 3) Breaking strength which evaluates the stress coordinate on a stress-strain curve at the point of rupture. Multiwalled carbon nanotubes, in particular, have the highest tensile strength of any material yet measured, with a tensile strength of 63 GPa having been achieved. Moreover, theoretical calculations have indicated possible tensile strengths of CNTs of about 300 GPa. Thus, CNT-infused fiber materials are expected to have substantially higher ultimate strength compared to the parent fiber material. As described above, the increase in tensile strength will depend on the exact nature of the CNTs used as well as the density and distribution on the fiber material. CNT-infused fiber materials can exhibit a two to three times increase in tensile properties, for example. Exemplary CNT-infused fiber materials can have as high as three times the shear strength as the parent unfunctionalized fiber material and as high as 2.5 times the compression strength. Young's modulus is a measure of the stiffness of an isotropic elastic material. It is defined as the ratio of the uniaxial stress over the uniaxial strain in the range of stress in which Hooke's Law holds. This can be experimentally determined from the slope of a stress-strain curve created during tensile tests conducted on a sample of the material.

To prepare the composites of the invention carbon nanotubes are infused a fiber material; that is, the carbon nanotubes are synthesized directly on the fiber material. In some embodiments, this is accomplished by first disposing a nanotube-forming catalyst on the fiber. A number of preparatory processes can be performed prior to this catalyst deposition.

In some embodiments, the fiber material can be optionally treated with plasma to prepare the surface to accept the catalyst. For example, a plasma treated glass fiber material can provide a roughened glass fiber surface in which the CNT-forming catalyst can be deposited. In some embodiments, the plasma also serves as to “clean” the fiber surface. The plasma process for “roughing” the surface of the fiber thus facilitates catalyst deposition. The roughness is typically on the scale of nanometers. In the plasma treatment process craters or depressions are formed that are nanometers deep and nanometers in diameter. Such surface modification can be achieved using a plasma of any one or more of a variety of different gases, including, without limitation, argon, helium, oxygen, ammonia, nitrogen and hydrogen.

In some embodiments, where a fiber material being employed has a sizing material associated with it, such sizing can be optionally removed prior to catalyst deposition. Optionally, the sizing can be removed after catalyst deposition. In some embodiment, sizing removal can be accomplished during CNT synthesis or just prior to CNT synthesis in a pre-heat step. In yet further embodiments, some sizing agents can remain throughout the entire CNT synthesis process.

Yet another optional step prior to or concomitant with deposition of the CNT-form catalyst is application of a barrier coating to the fiber material. Barrier coatings are materials designed to protect the integrity of sensitive fiber materials, such as carbon fiber, organic fibers, metal fibers, and the like. Such a coating can include for example an alkoxysilane, an alumoxane, alumina nanoparticles, spin on glass and glass nanoparticles. The CNT-forming catalyst can be added to the uncured barrier coating material and then applied to the fiber material together, in one embodiment. In other embodiments the barrier coating material can be added to the fiber material prior to deposition of the CNT-forming catalyst. In such embodiments, the barrier coating can be partially cured prior to catalyst deposition. The barrier coating material can be of a thickness sufficiently thin to allow exposure of the CNT-forming catalyst to the carbon feedstock for subsequent CVD growth. In some embodiments, the thickness is less than or about equal to the effective diameter of the CNT-forming catalyst. Once the CNT-forming catalyst and barrier coating are in place, the barrier coating can be fully cured. In some embodiments, the thickness of the barrier coating can be greater than the effective diameter of the CNT-forming catalyst so long as it still permits access of CNT forming reagents to the site of the catalysts. Such barrier coatings can be sufficiently porous to allow access of carbon feedstock to the CNT catalyst.

Without being bound by theory, the barrier coating can serve as an intermediate layer between the fiber material and the CNTs and can also assist in mechanically infusing the CNTs to the glass fiber material. Such mechanical infusion provides a robust system in which the fiber material still serves as a platform for organizing the CNTs and the benefits of mechanical infusion with a barrier coating are similar to the indirect type fusion described herein above. Moreover, the benefit of including a barrier coating is the immediate protection it provides the fiber material from chemical damage due to exposure to moisture and/or any thermal damage due to heating of the fiber material at the temperatures used to promote CNT growth.

As described further below, the catalyst can be prepared as a liquid solution that contains CNT-forming catalyst that comprise transition metal nanoparticles. The diameters of the synthesized nanotubes are related to the size of the metal particles as described above.

Carbon nanotube synthesis can be based on a chemical vapor deposition (CVD) process which occurs at elevated temperatures. The specific temperature is a function of catalyst choice, but can typically be in a range of about 500 to 1000° C. Accordingly, CNT synthesis involves heating the fiber material to a temperature in the aforementioned range to support carbon nanotube synthesis.

CVD-promoted nanotube growth on the catalyst-laden fiber material is then performed. The CVD process can be promoted by, for example, a carbon-containing feedstock gas such as acetylene, ethylene, and/or ethanol. The CNT synthesis processes generally use an inert gas (nitrogen, argon, helium) as a primary carrier gas. The carbon feedstock is provided in a range from between about 0% to about 15% of the total mixture. A substantially inert environment for CVD growth can be prepared by removal of moisture and oxygen from the growth chamber.

In the CNT synthesis process, CNTs grow at the sites of a CNT-forming transition metal nanoparticle catalyst. The presence of a strong plasma-creating electric field can be optionally employed to affect nanotube growth. That is, the growth tends to follow the direction of the electric field. By properly adjusting the geometry of the plasma spray and electric field, vertically-aligned CNTs (i.e., perpendicular to the glass fiber material) can be synthesized. Under certain conditions, even in the absence of a plasma, closely-spaced nanotubes can maintain a substantially vertical growth direction resulting in a dense array of CNTs resembling a carpet or forest.

The operation of disposing a catalyst on the fiber material can be accomplished by spraying or dip coating a solution or by gas phase deposition via, for example, a plasma process. Thus, in some embodiments, after forming a solution of a catalyst in a solvent, catalyst can be applied by spraying or dip coating the fiber material with the solution, or combinations of spraying and dip coating. Either technique, used alone or in combination, can be employed once, twice, thrice, four times, up to any number of times to provide a fiber material that is sufficiently uniformly coated with CNT-forming catalyst. When dip coating is employed, for example, a fiber material can be placed in a first dip bath for a first residence time in the first dip bath. When employing a second dip bath, the fiber material can be placed in the second dip bath for a second residence time. For example, fiber materials can be subjected to a solution of CNT-forming catalyst for between about 3 seconds to about 90 seconds depending on the dip configuration and linespeed. Employing spraying or dip coating processes, a fiber material with a surface density of catalyst of less than about 5% surface coverage to as high as about 80% coverage, in which the CNT-forming catalyst nanoparticles are nearly monolayer. In some embodiments, the process of coating the CNT-forming catalyst on the fiber material should produce no more than a monolayer. For example, CNT growth on a stack of CNT-forming catalyst can erode the degree of infusion of the CNT to the fiber material. In other embodiments, the transition metal catalyst can be deposited on the fiber material using evaporation techniques, electrolytic deposition techniques, and other processes known to those skilled in the art, such as addition of the transition metal catalyst to a plasma feedstock gas as a metal organic, metal salt or other composition promoting gas phase transport.

Because processes to manufacture CNT-infused fibers are designed to be continuous, a spoolable fiber material can be dip-coated in a series of baths where dip coating baths are spatially separated. In a continuous process in which nascent fibers are being generated de novo, such as newly formed glass fibers from a furnace, dip bath or spraying of CNT-forming catalyst can be the first step after sufficiently cooling the newly formed fiber material. In some embodiments, cooling of newly formed glass fibers can be accomplished with a cooling jet of water which has the CNT-catalyst particles dispersed therein.

In some embodiments, application of a CNT-forming catalyst can be performed in lieu of application of a sizing when generating a fiber and infusing it with CNTs in a continuous process. In other embodiments, the CNT-forming catalyst can be applied to newly formed fibers in the presence of other sizing agents. Such simultaneous application of CNT-forming catalyst and other sizing agents can provide the CNT-forming catalyst in surface contact with the fiber material to insure CNT infusion. In yet further embodiments, the CNT-forming catalyst can be applied to nascent fibers by spray or dip coating while the fiber material is in a sufficiently softened state, for example, near or below the annealing temperature, such that CNT-forming catalyst is slightly embedded in the surface of the fibers. When depositing the CNT-forming catalyst on hot glass fiber materials, for example, care should be given to not exceed the melting point of the CNT-forming catalyst causing the fusion of nanoparticles resulting in loss of control of the CNT characteristics, such as CNT diameter, for example.

A CNT-catalyst solution employed can be a transition metal nanoparticle which can be any d-block transition metal. In addition, the nanoparticles can include alloys and non-alloy mixtures of d-block metals in elemental form or in salt form, and mixtures thereof. Such salt forms include, without limitation, oxides, carbides, and nitrides, acetates, nitrates, and the like. Non-limiting exemplary transition metal NPs include Ni, Fe, Co, Mo, Cu, Pt, Au, and Ag and salts thereof and mixtures thereof. In some embodiments, such CNT-forming catalysts are disposed on the fiber by applying or infusing a CNT-forming catalyst directly to the fiber material. Many nanoparticle transition metal catalysts are readily commercially available from a variety of suppliers, including, for example, Ferrotec Corporation (Bedford, N.H.).

Catalyst solutions used for applying the CNT-forming catalyst to the fiber material can be in any common solvent that allows the CNT-forming catalyst to be uniformly dispersed throughout. Such solvents can include, without limitation, water, acetone, hexane, isopropyl alcohol, toluene, ethanol, methanol, tetrahydrofuran (THF), cyclohexane or any other solvent with controlled polarity to create an appropriate dispersion of the CNT-forming catalyst nanoparticles. Concentrations of CNT-forming catalyst can be in a range from about 1:1 to 1:10000 catalyst to solvent.

In some embodiments, after applying the CNT-forming catalyst to the fiber material, the fiber material can be optionally heated to a softening temperature. This can aid in embedding the CNT-forming catalyst in the surface of the fiber material and can encourage seeded growth and prevent tip growth where the catalyst floats at the tip of the leading edge growing CNT. In some embodiments heating of the fiber material after disposing the catalyst on the fiber material can be at a temperature that is between about 500° C. and 1000° C. Heating to such temperatures, which can be used for CNT growth, can serve to remove any pre-existing sizing agents on the fiber material allowing deposition of the CNT-forming catalyst directly on the fiber. In some embodiments, the CNT-forming catalyst can also be placed on the surface of a sizing coating prior to heating. The heating step can be used to remove sizing while leaving the catalyst disposed on the fiber surface. Heating at these temperatures can be performed prior to or substantially simultaneously with introduction of a carbon feedstock for CNT growth.

In some embodiments, the CNT infusion process includes removing sizing agents from a fiber material, applying a CNT-forming catalyst to the fiber material after sizing removal, heating the fiber material to at least 500° C., and synthesizing carbon nanotubes on the fiber material. In some embodiments, operations of the CNT-infusion process include removing sizing from a fiber material, applying a CNT-forming catalyst to the fiber, heating the fiber to CNT-synthesis temperature and spraying carbon plasma onto the catalyst-laden fiber material. Thus, where commercial fiber materials are employed, processes for constructing CNT-infused fibers can include a discrete step of removing sizing from the fiber material before disposing the catalyst on the fiber material. Depending on the commercial sizing present, if it is not removed, then the CNT-forming catalyst may not be in surface contact with the fiber material, and this can prevent CNT fusion. In some embodiments, where sizing removal is assured under the CNT synthesis conditions, sizing removal can be performed after catalyst deposition but just prior to or during providing a carbon feedstock.

The step of synthesizing carbon nanotubes can include numerous techniques for forming carbon nanotubes, including, without limitation, micro-cavity, thermal or plasma-enhanced CVD techniques, laser ablation, arc discharge, and high pressure carbon monoxide (HiPCO). During CVD, in particular, a sized fiber material with CNT-forming catalyst disposed thereon, can be used directly. In some embodiments, any conventional sizing agents can be removed during CNT synthesis. In other embodiments other sizing agents are not removed, but do not hinder CNT synthesis and infusion to the fiber material due to the diffusion of the carbon feedstock through the sizing. In some embodiments, acetylene gas is ionized to create a jet of cold carbon plasma for CNT synthesis. The plasma is directed toward the catalyst-bearing fiber material. Thus, in some embodiments synthesizing CNTs on a fiber material includes (a) forming a carbon plasma; and (b) directing the carbon plasma onto the catalyst disposed on the fiber material. The diameters of the CNTs that are grown are dictated by the size of the CNT-forming catalyst. In some embodiments, a sized fiber substrate is heated to between about 550 to about 800° C. to facilitate CNT synthesis. To initiate the growth of CNTs, two gases are bled into the reactor: a process gas such as argon, helium, or nitrogen, and a carbon-containing gas, such as acetylene, ethylene, ethanol or methane. CNTs grow at the sites of the CNT-forming catalyst.

In some embodiments, a CVD growth can be plasma-enhanced. A plasma can be generated by providing an electric field during the growth process. CNTs grown under these conditions can follow the direction of the electric field. Thus, by adjusting the geometry of the reactor vertically aligned carbon nanotubes can be grown radially about a cylindrical fiber. In some embodiments, a plasma is not required for radial growth about the fiber. For fiber materials that have distinct sides such as tapes, mats, fabrics, plies, and the like, catalyst can be disposed on one or both sides and correspondingly, CNTs can be grown on one or both sides as well.

As described above, CNT-synthesis is performed at a rate sufficient to provide a continuous process for functionalizing spoolable fiber materials. Numerous apparatus configurations facilitate such continuous synthesis as exemplified below.

In some embodiments, CNT-infused fiber materials can be constructed in an “all plasma” process. In such embodiments, fiber materials pass through numerous plasma-mediated steps to form the final CNT-infused product. The first of the plasma processes, can include a step of fiber surface modification. This is a plasma process for “roughing” the surface of the fiber material to facilitate catalyst deposition, as described above. As described above, surface modification can be achieved using a plasma of any one or more of a variety of different gases, including, without limitation, argon, helium, oxygen, ammonia, hydrogen, and nitrogen.

After surface modification, the fiber material proceeds to catalyst application. This is a plasma process for depositing the CNT-forming catalyst on the fibers. The CNT-forming catalyst is typically a transition metal as described above. The transition metal catalyst can be added to a plasma feedstock gas as a precursor in the form of a ferrofluid, a metal organic, metal salt or other composition for promoting gas phase transport. The catalyst can be applied at room temperature in the ambient environment with neither vacuum nor an inert atmosphere being required. In some embodiments, the fiber material is cooled prior to catalyst application.

Continuing an all-plasma process, carbon nanotube synthesis occurs in a CNT-growth reactor. This can be achieved through the use of plasma-enhanced chemical vapor deposition, wherein carbon plasma is sprayed onto the catalyst-laden fibers. Since carbon nanotube growth occurs at elevated temperatures (typically in a range of about 500 to 1000° C. depending on the catalyst), the catalyst-laden fibers can be heated prior to exposing to the carbon plasma. For the infusion process, the fiber material can be optionally heated until it softens. After heating, the fiber material is ready to receive the carbon plasma. The carbon plasma is generated, for example, by passing a carbon containing gas such as acetylene, ethylene, ethanol, and the like, through an electric field that is capable of ionizing the gas. This cold carbon plasma is directed, via spray nozzles, to the fiber material. The fiber material can be in close proximity to the spray nozzles, such as within about 1 centimeter of the spray nozzles, to receive the plasma. In some embodiments, heaters are disposed above the fiber material at the plasma sprayers to maintain the elevated temperature of the fiber material.

Another configuration for continuous carbon nanotube synthesis involves a special rectangular reactor for the synthesis and growth of carbon nanotubes directly on fiber materials. The reactor can be designed for use in a continuous in-line process for producing carbon-nanotube bearing fibers. In some embodiments, CNTs are grown via a chemical vapor deposition (“CVD”) process at atmospheric pressure and at elevated temperature in the range of about 550° C. to about 800° C. in a multi-zone reactor. The fact that the synthesis occurs at atmospheric pressure is one factor that facilitates the incorporation of the reactor into a continuous processing line for CNT-on-fiber synthesis. Another advantage consistent with in-line continuous processing using such a zone reactor is that CNT growth occurs in a seconds, as opposed to minutes (or longer) as in other procedures and apparatus configurations typical in the art.

CNT synthesis reactors in accordance with the various embodiments include the following features:

Rectangular Configured Synthesis Reactors: The cross section of a typical CNT synthesis reactor known in the art is circular. There are a number of reasons for this including, for example, historical reasons (cylindrical reactors are often used in laboratories) and convenience (flow dynamics are easy to model in cylindrical reactors, heater systems readily accept circular tubes (quartz, etc.), and ease of manufacturing. Departing from the cylindrical convention, the present invention provides a CNT synthesis reactor having a rectangular cross section. The reasons for the departure are as follows: 1. Since many fiber materials that can be processed by the reactor are relatively planar such as flat tape or sheet-like in form, or a spread tow or roving, a circular cross section is an inefficient use of the reactor volume. This inefficiency results in several drawbacks for cylindrical CNT synthesis reactors including, for example, a) maintaining a sufficient system purge; increased reactor volume requires increased gas flow rates to maintain the same level of gas purge. This results in a system that is inefficient for high volume production of CNTs in an open environment; b) increased carbon feedstock gas flow; the relative increase in inert gas flow, as per a) above, requires increased carbon feedstock gas flows. Consider that the volume of an exemplary 12K glass fiber roving is 2000 times less than the total volume of a synthesis reactor having a rectangular cross section. In an equivalent growth cylindrical reactor (i.e., a cylindrical reactor that has a width that accommodates the same planarized glass fiber material as the rectangular cross-section reactor), the volume of the glass fiber material is 17,500 times less than the volume of the chamber. Although gas deposition processes, such as CVD, are typically governed by pressure and temperature alone, volume can have a significant impact on the efficiency of deposition. With a rectangular reactor there is a still excess volume. This excess volume facilitates unwanted reactions; yet a cylindrical reactor has about eight times that volume. Due to this greater opportunity for competing reactions to occur, the desired reactions effectively occur more slowly in a cylindrical reactor chamber. Such a slow down in CNT growth, is problematic for the development of a continuous process. One benefit of a rectangular reactor configuration is that the reactor volume can be decreased by using a small height for the rectangular chamber to make this volume ratio better and reactions more efficient. In some embodiments of the present invention, the total volume of a rectangular synthesis reactor is no more than about 3000 times greater than the total volume of a fiber material being passed through the synthesis reactor. In some further embodiments, the total volume of the rectangular synthesis reactor is no more than about 4000 times greater than the total volume of the fiber material being passed through the synthesis reactor. In some still further embodiments, the total volume of the rectangular synthesis reactor is less than about 10,000 times greater than the total volume of the fiber material being passed through the synthesis reactor. Additionally, it is notable that when using a cylindrical reactor, more carbon feedstock gas is required to provide the same flow percent as compared to reactors having a rectangular cross section. It should be appreciated that in some other embodiments, the synthesis reactor has a cross section that is described by polygonal forms that are not rectangular, but are relatively similar thereto and provide a similar reduction in reactor volume relative to a reactor having a circular cross section; c) problematic temperature distribution; when a relatively small-diameter reactor is used, the temperature gradient from the center of the chamber to the walls thereof is minimal. But with increased size, such as would be used for commercial-scale production, the temperature gradient increases. Such temperature gradients result in product quality variations across a fiber material substrate (i.e., product quality varies as a function of radial position). This problem is substantially avoided when using a reactor having a rectangular cross section. In particular, when a planar substrate is used, reactor height can be maintained constant as the size of the substrate scales upward. Temperature gradients between the top and bottom of the reactor are essentially negligible and, as a consequence, thermal issues and the product-quality variations that result are avoided. 2. Gas introduction: Because tubular furnaces are normally employed in the art, typical CNT synthesis reactors introduce gas at one end and draw it through the reactor to the other end. In some embodiments disclosed herein, gas can be introduced at the center of the reactor or within a target growth zone, symmetrically, either through the sides or through the top and bottom plates of the reactor. This improves the overall CNT growth rate because the incoming feedstock gas is continuously replenishing at the hottest portion of the system, which is where CNT growth is most active. This constant gas replenishment is an important aspect to the increased growth rate exhibited by the rectangular CNT reactors.

Zoning. Chambers that provide a relatively cool purge zone depend from both ends of the rectangular synthesis reactor. It has been determined that if hot gas were to mix with the external environment (i.e., outside of the reactor), there would be an increase in degradation of the fiber material. The cool purge zones provide a buffer between the internal system and external environments. Typical CNT synthesis reactor configurations known in the art typically require that the substrate is carefully (and slowly) cooled. The cool purge zone at the exit of the present rectangular CNT growth reactor achieves the cooling in a short period of time, as required for the continuous in-line processing.

Non-contact, hot-walled, metallic reactor. In some embodiments, a hot-walled reactor is made of metal is employed, in particular stainless steel. This may appear counterintuitive because metal, and stainless steel in particular, is more susceptible to carbon deposition (i.e., soot and by-product formation). Thus, most CNT reactor configurations use quartz reactors because there is less carbon deposited, quartz is easier to clean, and quartz facilitates sample observation. However, it has been observed that the increased soot and carbon deposition on stainless steel results in more consistent, faster, more efficient, and more stable CNT growth. Without being bound by theory it has been indicated that, in conjunction with atmospheric operation, the CVD process occurring in the reactor is diffusion limited. That is, the catalyst is “overfed;” too much carbon is available in the reactor system due to its relatively higher partial pressure (than if the reactor was operating under partial vacuum). As a consequence, in an open system—especially a clean one—too much carbon can adhere to catalyst particles, compromising their ability to synthesize CNTs. In some embodiments, the rectangular reactor is intentionally run when the reactor is “dirty,” that is with soot deposited on the metallic reactor walls. Once carbon deposits to a monolayer on the walls of the reactor, carbon will readily deposit over itself. Since some of the available carbon is “withdrawn” due to this mechanism, the remaining carbon feedstock, in the form of radicals, react with the catalyst at a rate that does not poison the catalyst. Existing systems run “cleanly” which, if they were open for continuous processing, would produce a much lower yield of CNTs at reduced growth rates.

Although it is generally beneficial to perform CNT synthesis “dirty” as described above, certain portions of the apparatus, such as gas manifolds and inlets, can nonetheless negatively impact the CNT growth process when soot creates blockages. In order to combat this problem, such areas of the CNT growth reaction chamber can be protected with soot inhibiting coatings such as silica, alumina, or MgO. In practice, these portions of the apparatus can be dip-coated in these soot inhibiting coatings. Metals such as INVAR® can be used with these coatings as INVAR has a similar CTE (coefficient of thermal expansion) ensuring proper adhesion of the coating at higher temperatures, preventing the soot from significantly building up in critical zones.

Combined Catalyst Reduction and CNT Synthesis. In the CNT synthesis reactor disclosed herein, both catalyst reduction and CNT growth occur within the reactor. This is significant because the reduction step cannot be accomplished timely enough for use in a continuous process if performed as a discrete operation. In a typical process known in the art, a reduction step typically takes 1-12 hours to perform. Both operations occur in a reactor in accordance with the present invention due, at least in part, to the fact that carbon feedstock gas is introduced at the center of the reactor, not the end as would be typical in the art using cylindrical reactors. The reduction process occurs as the fibers enter the heated zone; by this point, the gas has had time to react with the walls and cool off prior to reacting with the catalyst and causing the oxidation reduction (via hydrogen radical interactions). It is this transition region where the reduction occurs. At the hottest isothermal zone in the system, the CNT growth occurs, with the greatest growth rate occurring proximal to the gas inlets near the center of the reactor.

In some embodiments, when loosely affiliated fiber materials including tows or rovings are employed, such as glass roving for example, the continuous process can include steps that spread out the strands and/or filaments of the tow or roving. Thus, as a tow or roving is unspooled it can be spread using a vacuum-based fiber spreading system, for example. When employing sized glass fiber rovings, for example, which can be relatively stiff, additional heating can be employed in order to “soften” the roving to facilitate fiber spreading. The spread fibers which comprise individual filaments can be spread apart sufficiently to expose an entire surface area of the filaments, thus allowing the roving to more efficiently react in subsequent process steps. For example, a spread tow or roving can pass through a surface treatment step that is composed of a plasma system as described above. The roughened, spread fibers then can pass through a CNT-forming catalyst dip bath. The result is fibers of the glass roving that have catalyst particles distributed radially on their surface. The catalyzed-laden fibers of the roving then enter an appropriate CNT growth chamber, such as the rectangular chamber described above, where a flow through atmospheric pressure CVD or PE-CVD process is used to synthesize the CNTs at rates as high as several microns per second. The fibers of the roving, now with radially aligned CNTs, exit the CNT growth reactor.

It is understood that modifications which do not substantially affect the activity of the various embodiments of this invention are also included within the definition of the invention provided herein. Accordingly, the following examples are intended to illustrate but not limit the present invention.

### Example I

This example shows how a glass fiber material can be infused with CNTs in a continuous process and used in a ballistic damage sensing application. In this case, an array of short CNTs is desirable for enhanced damage detection resolution.

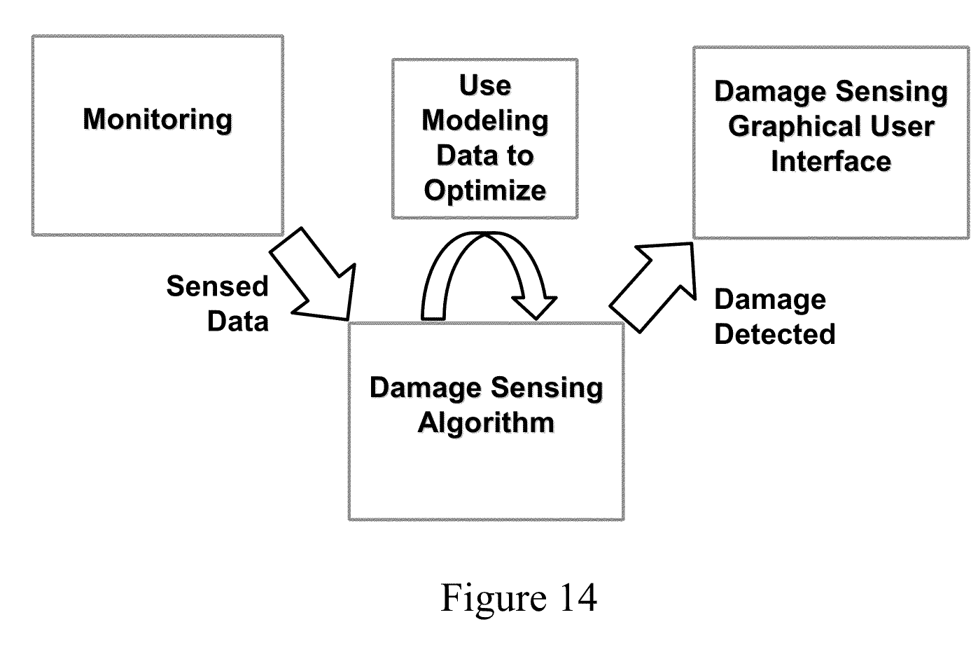

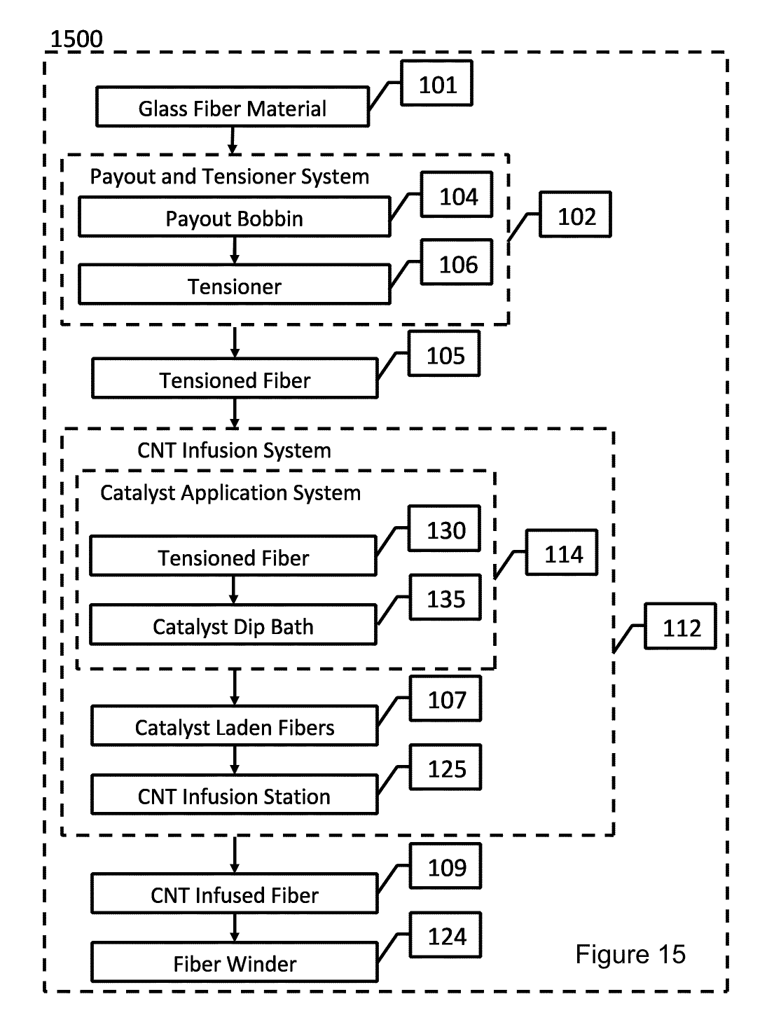

FIG. 14 depicts system 1500 for producing CNT-infused fiber in accordance with the illustrative embodiment of the present invention. System 1500 includes a glass fiber material payout and tensioner system 102, CNT-infusion system 112, and fiber winder 124, interrelated as shown.

Payout and tension system 102 includes payout bobbin 104 and tensioner 106. The payout bobbin holds fiber spools and delivers glass fiber material 101 to the process at a linespeed of 9 ft/min; the fiber tension is maintained within 1-5 lbs via tensioner 106. Payout and tension station 102 is routinely used in the fiber industry; those skilled in the art will be familiar with their design and use.

Tensioned fiber 105 is delivered to CNT-infusion system 112. Station 112 includes catalyst application system 114 and micro-cavity CVD based CNT infusion station 125.

In this illustrative example, the catalyst solution is applied via a dip process, such as by passing tensioned fiber 130 through a dip bath 135. In this example, a catalyst solution consisting of a volumetric ratio of 1 part ferrofluid nanoparticle solution and 100 parts hexane is used. At the process linespeed for CNT-infused fiber targeted at improving ILSS, the fiber will remain in the dip bath for 10 seconds. The catalyst can be applied at room temperature in the ambient environment with neither vacuum nor an inert atmosphere required.

Catalyst laden glass fiber 107 is then advanced to the CNT infusion station 125 consisting of a pre-growth cool inert gas purge zone, a CNT growth zone, and a post-growth gas purge zone. Room temperature nitrogen gas is introduced to the pre-growth purge zone in order to cool exiting gas from the CNT growth zone as described above. The exiting gas is cooled to below 250° C. via the rapid nitrogen purge to prevent fiber oxidation. Fibers enter the CNT growth zone where elevated temperatures heat a mixture of 97.7% mass flow inert gas (nitrogen) and 2.3% mass flow carbon containing feedstock gas (acetylene) which is introduced centrally via a gas manifold. In this example the length of the system is 3 feet long and the temperature in the CNT growth zone is 750° C. Catalyst laden fibers are exposed to the CNT growth environment for 20 seconds in this example, resulting in 5 micron long with a ˜4% volume percentage CNTs infused to the glass fiber surface. The CNT-infused glass fibers finally pass through the post-growth purge zone which at 250° C. cools the fiber as well as the exiting gas to prevent oxidation to the fiber surface and CNTs.

CNT-infused fiber 109 is collected on fiber winder 124, where it is wrapped around and stored on spools.

Processed CNT-infused fiber 109 is then wound in a unidirectional direction about a plate using a filament winder (not shown). Each unidirectional fiber bundle is wound such that each adjacent bundle is in contact. Four layers of unidirectional fiber is wound on a 6″×6″ plate.

Wound fiber on a 7″×7″ plate is infused with thermoset resin, EPON 828, using a vacuum assisted resin transfer method (VARTM), where the wound material is bagged and placed under vacuum. Resin is transferred through the structure using the vacuum. The resulting structure is cured in a heated press based on the resin manufacturers requirements.

Cured composite skin is cut into a 6.5″×6″ panel. The panel is masked to expose twelve equally spaced electrode points parallel to the fiber direction (similar to those shown in FIG. 4), which are sanded to remove the resin rich surface layer. Gold electrode contacts are deposited using sputter deposition.

An additional undirectional panel is prepared similarly to what is described in paragraphs 119-128. These panels are bonded to a multi-layer glass composite ballistic panel in a configuration shown in FIG. 5: 0° fiber direction layer—insulating glass fiber layer—90° C. fiber direction layer—ballistic panel. A typical two part epoxy adhesive is used to bond each layer of the composite structure.

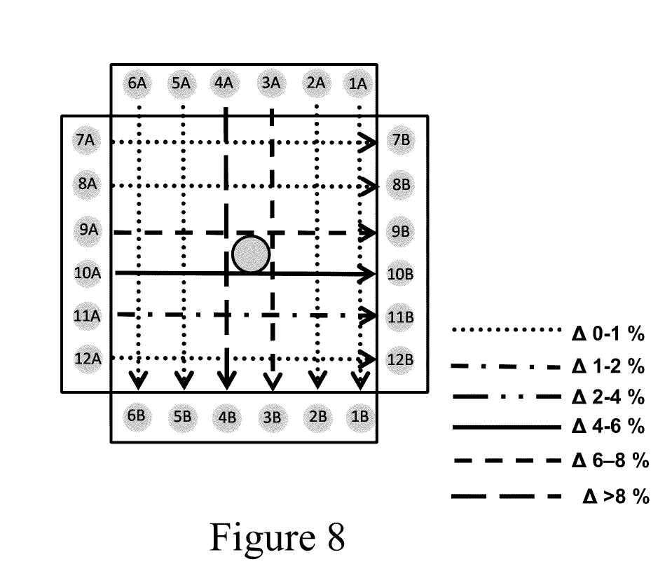

A shear punch is used to simulate ballistic damage to the final composite structure. An initial resistance reading is taken across each electrode pair labeled 1A-B through 12A-B, given an input signal of 10 Hz and amplitude of 0.5 volts. A shear punch of size ½″ diameter used to simulate a ballistic round is pressed through the ballistic panel using an Instron compression testing machine. Depending on the placement of the simulated damage, changes in resistance is noted in various sets of electrode pairs. In the case of a hole at the center of the panel, ˜3% changes in resistance are observed for electrode pairs 6A-B and 7A-B (similarly illustrated in FIG. 8) for both detection layers (0° and 90°). The amount of change in resistance observed provides information describing the type and severity of ballistic damage incurred and the electrode pair affected provide information about the damage location.

### Example II

This example shows how a glass fiber material can be infused with CNTs in a continuous process and used in a impact damage sensing application. In this case, an array of short CNTs is desirable for enhanced damage detection resolution.

FIG. 14 depicts system 1500 for producing CNT-infused fiber in accordance with the illustrative embodiment of the present invention. System 1500 includes a glass fiber material payout and tensioner system 102, CNT-infusion system 112, and fiber winder 124, interrelated as shown.

Payout and tension system 102 includes payout bobbin 104 and tensioner 106. The payout bobbin holds fiber spools and delivers glass fiber material 101 to the process at a linespeed of 12 ft/min; the fiber tension is maintained within 1-5 lbs via tensioner 106. Payout and tension station 102 is routinely used in the fiber industry; those skilled in the art will be familiar with their design and use.

Tensioned fiber 105 is delivered to CNT-infusion system 112. Station 112 includes catalyst application system 114 and micro-cavity CVD based CNT infusion station 125.

In this illustrative example, the catalyst solution is applied via a dip process, such as by passing tensioned fiber 130 through a dip bath 135. In this example, a catalyst solution consisting of a volumetric ratio of 1 part ferrofluid nanoparticle solution and 100 parts hexane is used. At the process linespeed for CNT-infused fiber targeted at improving ILSS, the fiber will remain in the dip bath for 7.5 seconds. The catalyst can be applied at room temperature in the ambient environment with neither vacuum nor an inert atmosphere required.

Catalyst laden glass fiber 107 is then advanced to the CNT infusion station 125 consisting of a pre-growth cool inert gas purge zone, a CNT growth zone, and a post-growth gas purge zone. Room temperature nitrogen gas is introduced to the pre-growth purge zone in order to cool exiting gas from the CNT growth zone as described above. The exiting gas is cooled to below 250° C. via the rapid nitrogen purge to prevent fiber oxidation. Fibers enter the CNT growth zone where elevated temperatures heat a mixture of 97.7% mass flow inert gas (nitrogen) and 2.3% mass flow carbon containing feedstock gas (acetylene) which is introduced centrally via a gas manifold. In this example the length of the system is 3 feet long and the temperature in the CNT growth zone is 750° C. Catalyst laden fibers are exposed to the CNT growth environment for 15 seconds in this example, resulting in 3 micron long with a ˜3.5% volume percentage CNTs infused to the glass fiber surface. The CNT-infused glass fibers finally pass through the post-growth purge zone which at 250° C. cools the fiber as well as the exiting gas to prevent oxidation to the fiber surface and CNTs.

CNT-infused fiber 109 is collected on fiber winder 124, where it is wrapped around and stored on spools.

Processed CNT-infused fiber 109 is then wound in a 90° direction about a picture frame plate (plate a hole cut out of the middle) using a filament winder (not shown). Each unidirectional fiber bundle is wound such that each adjacent bundle is in contact. Another layer in the 0° direction is wound over the 90° layer. The material at the center of the picture frame is cut creating a 3.25″×3.25″ fiber stacking of the configuration illustrated in FIG. 2A.

Stacked fiber structure is infused with thermoset resin, EPON 828, using a vacuum assisted resin transfer method (VARTM), where the 3.25″×3.25″ stacked fiber structure is bagged and placed under vacuum. Resin is transferred through the structure using the vacuum. The resulting infused material is cured in a heated press based on the resin manufacturers requirements.

Cured composite plate is cut into a 3″×3″ panel. A series of ⅛″ diameter holes are drilled into the structure along the periphery, resulting in three equally spaced holes along each side of the plate. Inside of each hole is coated with conductive silver paint and electrode wires are attached with appropriately sized hardware equally torqued creating a panel similar to that illustrated in FIG. 2B.

A drop test fixture is used to simulate impact damage to the final composite structure. An initial resistance and signal phase reading is taken across each electrode pair where electrode 1 is the top center and the electrode number increases in the clockwise direction to electrode 8. Each electrode acts as a transmitter while a signal is taken by each of the remaining electrodes. This role is passed clockwise to each electrode until all electrodes are used as a transmitter. Given an input signal of 1 kHz and amplitude of 1.0 volts, the resulting data array provides information about the initial damage state of the composite structure. Using the drop test fixture, a ball shaped weight of 3700 grams is dropped from a 125 cm height onto the surface of the panel to simulate impact damage. Once the drop test is complete, another resistance and signal phase reading is taken in the sample sequence as described above. In this case, a resistance change of 0.19% is observed across various sets of oppositely spaced electrode pairs, while 0.1-0.15° phase shifts represent the formation of cracks in the internal composite structure. The amount of change in resistance observed provides information describing severity of impact damage incurred and the phase shift provides information about the geometry of the internal cracks developed within the composite structure.

It is to be understood that the above-described embodiments are merely illustrative of the present invention and that many variations of the above-described embodiments can be devised by those skilled in the art without departing from the scope of the invention. For example, in this Specification, numerous specific details are provided in order to provide a thorough description and understanding of the illustrative embodiments of the present invention. Those skilled in the art will recognize, however, that the invention can be practiced without one or more of those details, or with other processes, materials, components, etc.

Furthermore, in some instances, well-known structures, materials, or operations are not shown or described in detail to avoid obscuring aspects of the illustrative embodiments. It is understood that the various embodiments shown in the Figures are illustrative, and are not necessarily drawn to scale. Reference throughout the specification to “one embodiment” or “an embodiment” or “some embodiments” means that a particular feature, structure, material, or characteristic described in connection with the embodiment(s) is included in at least one embodiment of the present invention, but not necessarily all embodiments. Consequently, the appearances of the phrase “in one embodiment,” “in an embodiment,” or “in some embodiments” in various places throughout the Specification are not necessarily all referring to the same embodiment. Furthermore, the particular features, structures, materials, or characteristics can be combined in any suitable manner in one or more embodiments. It is therefore intended that such variations be included within the scope of the following claims and their equivalents.

What is claimed is:

1. A composite comprising:
a) a matrix material; and
b) a first unidirectional array of carbon nanotube (CNT)-infused fibers disposed in at least a portion of said matrix material.

2. The composite of claim 1, wherein the matrix material is selected from a thermoset, a thermoplastic, a ceramic, and a cement.

3. The composite of claim 1, wherein the infused CNTs are selected from multi-walled CNTs, double-walled CNTs, single-walled CNTs; and mixtures thereof.

4. The composite of claim 3, wherein the infused CNTs are multi-walled CNTs.

5. The composite of claim 1, wherein the infused CNTs are aligned substantially along the fiber axis.

6. The composite of claim 1, wherein the infused CNTs are aligned substantially perpendicular to the fiber axis.

7. The composite of claim 1, wherein the infused CNTs are present in a range from between about 0.01 percent to about 1 percent by weight of the composite.

8. The composite of claim 1, wherein the infused CNTs range in length from between about 100 nanometers to about 5 microns.

9. The composite of claim 1, wherein the CNT-infused fibers are selected from glass fibers, aramid fibers, ceramic fibers, and mixtures thereof.

10. The composite of claim 1, wherein said first unidirectional array of CNT-infused fibers comprises a continuous fiber.

11. The composite of claim 1, wherein said first unidirectional array of CNT-infused fibers comprises a plurality of discontinuous fibers.

12. The composite of claim 1, wherein said first unidirectional array of CNT-infused fibers is disposed at the surface of the composite.

13. The composite of claim 1, further comprising a second unidirectional array of CNT-infused fibers.

14. The composite of claim 13, wherein said second unidirectional array of CNT-infused fibers is disposed at an angle from between about 0 degrees to about 90 degrees, relative to said first unidirectional array of CNT-infused fibers.

15. The composite of claim 13, further comprising an insulating layer disposed between said first unidirectional array of CNT-infused fibers and said second unidirectional array of CNT-infused fibers.

16. An article comprising:
a) a composite comprising:
i) a matrix material; and
ii) a first unidirectional array of carbon nanotube (CNT)-infused fibers disposed in at least a portion of said matrix material; and
b) a network of electrodes disposed about the periphery of said composite for sending and receiving an electrical charge.

17. The article of claim 16, further comprising sensing circuitry connected to the network of electrodes for detecting a change in resistance across the composite.

18. The article of claim 17, wherein the sensing circuitry is capable of measuring and mapping the location of strain, fatigue, damage, and/or cracks in said composite.

19. The article of claim 16, wherein the matrix material is selected from a thermoset, a thermoplastic, a ceramic, and a cement.

20. The article of claim 16, wherein CNTs of the CNT-infused fibers are, selected from multi-walled CNTs, double-walled CNTs, single-walled CNTs; and mixtures thereof.

21. The article of claim 20, wherein the infused CNTs are multi-walled CNTs.

22. The article of claim 16, wherein the infused CNTs are aligned substantially along the fiber axis.

23. The article of claim 16, wherein the infused CNTs are aligned substantially perpendicular to the fiber axis.

24. The article of claim 16, wherein the infused CNTs are present in a range from between about 0.01 percent to about 1 percent by weight of the composite.

25. The article of claim 16, wherein the infused CNTs range in length from between about 100 nanometers to about 5 microns.

26. The article of claim 16, wherein the CNT-infused fibers are selected from glass fibers, aramid fibers, ceramic fibers, and mixtures thereof.

27. The article of claim 16, wherein said first unidirectional array of CNT-infused fibers comprises a continuous fiber.

28. The article of claim 16, wherein said first unidirectional array of CNT-infused fibers comprises a plurality of discontinuous fibers.

29. The article of claim 16, wherein said first unidirectional array of CNT-infused fibers is disposed at the surface of the composite.

30. The article of claim 16, further comprising a second unidirectional array of CNT-infused fibers.

31. The article of claim 30, wherein said second unidirectional array of CNT-infused fibers is disposed at an angle from between about 0 degrees to about 90 degrees, relative to said first unidirectional array of CNT-infused fibers.

32. The article of claim 30, further comprising an insulating layer disposed between said first unidirectional array of CNT-infused fibers and said second unidirectional array of CNT-infused fibers.

33. The article of claim 16, wherein said a network of electrodes comprises a network of transmitting and receiving electrodes fabricated with silver paint.

34. The article of claim 16, wherein said a network of electrodes comprises a network of transmitting and receiving electrodes comprising embedded copper pins.

35. A system comprising:
A) an article, said article comprising:
i) a composite, said composite comprising:
a) a matrix material; and
b) a first unidirectional array of carbon nanotube (CNT)-infused fibers disposed in at least a portion of said matrix material; and
B) sensing circuitry connected to the composite for detecting a change in resistance across the composite.

36-79. (canceled)

80. The system of claim 35, further comprising a network of electrodes connecting said composite to said sensing circuitry.

81. The system of claim 80, further comprising a source for supplying current to said network of electrodes.

82. The system of claim 35, wherein the sensing circuitry is capable of measuring and mapping the location of strain, fatigue, damage, and/or cracks in said composite.

83. The system of claim 35, further comprising a computer equipped to receive resistance data from said sensing circuitry, said computer provided with software having a damage sensing algorithm.

84. The system of claim 83, further comprising a graphical user interface displaying the location of strain, fatigue, damage, and cracks in said composite.

85. The system of claim 35, wherein the matrix material is selected from a thermoset, a thermoplastic, a ceramic, and a cement.

86. The system of claim 35, wherein CNTs of the CNT-infused fibers are selected from multi-walled CNTs, double-walled CNTs, single-walled CNTs; and mixtures thereof.

87. The system of claim 86, wherein the infused CNTs are multi-walled CNTs.

88. The system of claim 35, wherein the infused CNTs are aligned substantially along the fiber axis.

89. The system of claim 35, wherein the infused CNTs are aligned substantially perpendicular to the fiber axis.

90. The system of claim 35, wherein the infused CNTs are present in a range from between about 0.01 percent to about 1 percent by weight of the composite.

91. The system of claim 35, wherein the infused CNTs range in length from between about 100 nanometers to about 5 microns.

92. The system of claim 35, wherein the CNT-infused fibers are selected from glass fibers, aramid fibers, ceramic fibers, and mixtures thereof.

93. The system of claim 35, wherein said first unidirectional array of CNT-infused fibers comprises a continuous fiber.

94. The system of claim 35, wherein said first unidirectional array of CNT-infused fibers comprises a plurality of discontinuous fibers.

95. The system of claim 35, wherein said first unidirectional array of CNT-infused fibers is disposed at the surface of the composite.

96. The system of claim 35, further comprising a second unidirectional array of CNT-infused fibers.

97. The system of claim 96, wherein said second unidirectional array of CNT-infused fibers is disposed at an angle from between about 0 degrees to about 90 degrees, relative to said first unidirectional array of CNT-infused fibers.

98. The system of claim 96, further comprising an insulating layer disposed between said first unidirectional array of CNT-infused fibers and said second unidirectional array of CNT-infused fibers.

99. The system of claim 35, wherein said network of transmitting and receiving electrodes comprises electrodes fabricated with silver paint.

100. The system of claim 35, wherein said network of transmitting and receiving electrodes comprises embedded copper pin electrodes.

101. A method comprising:
1) providing a system; said system comprising:
A) an article, said article comprising:
a composite, said composite comprising:
a) a matrix material; and
b) a first unidirectional array of carbon nanotube (CNT)-infused fibers disposed in at least a portion of said matrix material; and
B) sensing circuitry connected to the composite for detecting a change in resistance across the composite; and
2) supplying a current to the composite allowing the sensing circuitry to detect a change in resistance which relates to a flaw or defect in the composite.

102. The method of claim 101, further comprising means for determining a location of said flaw or defect in the composite based on an output of the sensing circuitry.

103. The method of claim 101, wherein said flaw or defect is selected from strain, fatigue, damage, and/or cracks in said composite.

104. The method of claim 101, wherein the system further comprises a computer equipped to receive resistance data from said sensing circuitry, said computer provided with software having a damage sensing algorithm.

105. The method of claim 104, further comprising a graphical user interface displaying the location of strain, fatigue, damage, and cracks in said composite.

106. The method of claim 101, wherein the matrix material is selected from a thermoset, a thermoplastic, a ceramic, and a cement.

107. The method of claim 101, wherein CNTs of the CNT-infused fibers are selected from multi-walled CNTs, double-walled CNTs, single-walled CNTs; and mixtures thereof.

108. The method of claim 107, wherein the infused CNTs are multi-walled CNTs.

109. The method of claim 101, wherein the infused CNTs are aligned substantially along the fiber axis.

110. The method of claim 101, wherein the infused CNTs are aligned substantially perpendicular to the fiber axis.

111. The method of claim 101, wherein the infused CNTs are present in a range from between about 0.01 percent to about 1 percent by weight of the composite.

112. The method of claim 101, wherein the infused CNTs range in length from between about 100 nanometers to about 5 microns.

113. The method of claim 101, wherein the CNT-infused fibers are selected from glass fibers, aramid fibers, ceramic fibers, and mixtures thereof.

114. The method of claim 101, wherein said first unidirectional array of CNT-infused fibers comprises a continuous fiber.

115. The method of claim 101, wherein said first unidirectional array of CNT-infused fibers comprises a plurality of discontinuous fibers.

116. The method of claim 101, wherein said first unidirectional array of CNT-infused fibers is disposed at the surface of the composite.

117. The method of claim 101, further comprising a second unidirectional array of CNT-infused fibers.

118. The method of claim 117, wherein said second unidirectional array of CNT-infused fibers is disposed at an angle from between about 0 degrees to about 90 degrees, relative to said first unidirectional array of CNT-infused fibers.

119. The method of claim 117, further comprising an insulating layer disposed between said first unidirectional array of CNT-infused fibers and said second unidirectional array of CNT-infused fibers.

120. The method of claim 101, further wherein the system further comprises a network of transmitting and receiving electrodes.

121. The method of claim 120, wherein said network of transmitting and receiving electrodes comprises electrodes fabricated with silver paint.

122. The method of claim 120, wherein said network of transmitting and receiving electrodes comprises embedded copper pin electrodes.
